(19) United States
(12) Patent Application Publication
(10) Pub. No.: US 2024/0288552 A1
(43) Pub. Date: Aug. 29, 2024

(54) SYSTEMS AND METHODS FOR MONITORING AND CONTROL OF LASER POWER IN A LIDAR DEVICE

(71) Applicant: VELODYNE LIDAR USA, INC., San Jose, CA (US)

(72) Inventors: Oren Milgrome, San Jose, CA (US); Danny Boby, San Jose, CA (US); Pravin Kumar Venkatesan, Fremont, CA (US)

(21) Appl. No.: 18/115,754

(22) Filed: Feb. 28, 2023

(51) Int. Cl. G01S 7/484; G01S 17/931

(52) U.S. Cl. CPC G01S 7/484; G01S 17/931

(57) ABSTRACT

A lidar device may include a first circuit comprising a transmitter configured to emit an optical signal, wherein a power level of the optical signal is based on an operating parameter; a power monitoring circuit coupled to the first circuit and configured to measure, during emission of the optical signal, an indication of the power level of the optical signal; and at least one processor configured to determine, based on a comparison of the measured indication of the power level to a nominal indication of the power level, whether to adjust the operating parameter.

### FIELD OF TECHNOLOGY

The present disclosure relates generally to lidar technology and, more specifically, to using power monitoring to control optical signal intensity and compensate for variations in operating conditions.

### BACKGROUND

Lidar (light detection and ranging) systems measure the attributes of their surrounding environments (e.g., shape of a target, contour of a target, distance to a target, etc.) by illuminating the environment with light (e.g., laser light) and measuring the reflected light with sensors. Differences in laser return times and/or wavelengths can then be used to make digital, three-dimensional (“3D”) representations of a surrounding environment. Lidar technology may be used in various applications including autonomous vehicles, advanced driver assistance systems, mapping, security, surveying, robotics, geology and soil science, agriculture, unmanned aerial vehicles, airborne obstacle detection (e.g., obstacle detection systems for aircraft), etc. Depending on the application and associated field of view, multiple optical transmitters and/or optical receivers may be used to produce images in a desired resolution. A lidar system with greater numbers of transmitters and/or receivers can generally generate larger numbers of pixels.

In a multi-channel lidar device, optical emitters can be paired with optical detectors to form multiple “channels.” In operation, each channel can include one or more emitters that emit optical signals (e.g., laser light) into the device's environment, and each channel can include one or more detectors that receive reflections of the optical signals from the environment. In this way, each channel can provide “point” measurements of the environment, which can be aggregated with the point measurements provided by the other channel(s) to form a “point cloud” of measurements of the environment.

The measurements collected by a lidar channel may be used to determine the distance (“range”) from the device to the surface in the environment that reflected the channel's transmitted optical signal back to the channel's receiver. In some cases, the range to a surface may be determined based on the time of flight of the channel's signal (e.g., the time elapsed from the transmitter's emission of the optical signal to the receiver's reception of the return signal reflected by the surface). In other cases, the range may be determined based on the wavelength (or frequency) of the return signal(s) reflected by the surface.

In some cases, lidar measurements may be used to determine the reflectance of the surface that reflects an optical signal. The reflectance of a surface may be determined based on the intensity of the return signal, which generally depends not only on the reflectance of the surface but also on the range to the surface, the emitted signal's glancing angle with respect to the surface, the power level of the channel's transmitter, the alignment of the channel's transmitter and receiver, and other factors.

The foregoing examples of the related art and limitations therewith are intended to be illustrative and not exclusive, and are not admitted to be “prior art.” Other limitations of the related art will become apparent to those of skill in the art upon a reading of the specification and a study of the drawings.

### SUMMARY

Systems and methods for measuring and controlling optical power at a lidar device are disclosed. According to one aspect of the present disclosure, a lidar device includes a first circuit including a transmitter configured to emit an optical signal, wherein a power level of the optical signal is based on an operating parameter; a power monitoring circuit coupled to the first circuit and configured to measure, during emission of the optical signal, an indication of the power level of the optical signal; and at least one processor configured to determine, based on a comparison of the measured indication of the power level to a nominal indication of the power level, whether to adjust the operating parameter.

According to another aspect of the present disclosure, a power monitoring and control method for a lidar device includes emitting, by a transmitter of the lidar device, an optical signal, wherein a power level of the optical signal is based on an operating parameter; measuring, by a power monitoring circuit during the emitting of the optical signal, an indication of the power level of the optical signal; and determining, based on a comparison of the measured indication of the power level to a nominal indication of the power level, whether to adjust the operating parameter.

The above and other preferred features, including various novel details of implementation and combination of events, will now be more particularly described with reference to the accompanying figures and pointed out in the claims. It will be understood that the particular systems and methods described herein are shown by way of illustration only and not as limitations. As will be understood by those skilled in the art, the principles and features described herein may be employed in various and numerous embodiments without departing from the scope of any of the present inventions. As can be appreciated from the foregoing and the following description, each and every feature described herein, and each and every combination of two or more such features, is included within the scope of the present disclosure provided that the features included in such a combination are not mutually inconsistent. In addition, any feature or combination of features may be specifically excluded from any embodiment of any of the present inventions.

The foregoing Summary, including the description of some embodiments, motivations therefor, and/or advantages thereof, is intended to assist the reader in understanding the present disclosure, and does not in any way limit the scope of any of the claims.

### BRIEF DESCRIPTION OF THE DRAWINGS

The accompanying figures, which are included as part of the present specification, illustrate the presently preferred embodiments and together with the general description given above and the detailed description of the preferred embodiments given below serve to explain and teach the principles described herein.

FIG. 1 is an illustration of an exemplary lidar system, in accordance with some embodiments.

FIG. 2A is an illustration of the operation of a lidar system, in accordance with some embodiments.

FIG. 2B is an illustration of optical components of a channel of a lidar system with a movable mirror, in accordance with some embodiments.

FIG. 2C is an illustration of an example of a 3D lidar system, in accordance with some embodiments.

FIG. 2D is a block diagram of a transmitter-receiver optical sub-assembly (TROSA), according to some embodiments.

FIG. 3 shows a block diagram of an exemplary power control module (“PCM”) in a lidar device, in accordance with some embodiments.

FIG. 4 shows a circuit of an exemplary PCM in a lidar device, in accordance with some embodiments.

FIGS. 5A and 5B show a flowchart of a method for monitoring and controlling optical power at a lidar device, in accordance with some embodiments.

FIG. 6 shows an exemplary timing diagram for controlling a PCM, in accordance with some embodiments.

FIG. 7 shows a flowchart of a method for controlling optical power at a lidar device, in accordance with some embodiments.

FIG. 8 is an illustration of an example continuous wave (CW) coherent lidar system, in accordance with some embodiments.

FIG. 9 is an illustration of an example frequency modulated continuous wave (FMCW) coherent lidar system, in accordance with some embodiments.

FIG. 10A is a plot of a frequency chirp as a function of time in a transmitted laser signal and reflected signal, in accordance with some embodiments.

FIG. 10B is a plot illustrating a beat frequency of a mixed signal, in accordance with some embodiments.

FIG. 11A is a diagram of a vehicle including a plurality of sensors, in accordance with some embodiments.

FIG. 11B is a block diagram of a silicon photonic integrated circuit (PIC) in accordance with some embodiments.

FIG. 12 is a block diagram of an example computer system, in accordance with some embodiments.

FIG. 13 is a block diagram of a computing device/information handling system, in accordance with some embodiments.

While the present disclosure is subject to various modifications and alternative forms, specific embodiments thereof have been shown by way of example in the drawings and will herein be described in detail. The present disclosure should not be understood to be limited to the particular forms disclosed, but on the contrary, the intention is to cover all modifications, equivalents, and alternatives falling within the spirit and scope of the present disclosure.

### DETAILED DESCRIPTION

Systems and methods for monitoring and controlling optical power levels of a lidar device are disclosed. It will be appreciated that for simplicity and clarity of illustration, where considered appropriate, reference numerals may be repeated among the figures to indicate corresponding or analogous elements. In addition, numerous specific details are set forth in order to provide a thorough understanding of the example embodiments described herein. However, it will be understood by those of ordinary skill in the art that the example embodiments described herein may be practiced without these specific details.

Three of the most significant technical challenges faced by the lidar industry are (1) reducing the manufacturing cost for lidar devices while maintaining existing performance levels, (2) improving the reliability of lidar devices under automotive operating conditions (e.g., weather, temperature, and mechanical vibration), and (3) increasing the range of lidar devices while maintaining good near-field performance. One approach to reducing manufacturing costs is to reduce the amount of hardware (e.g., channels, transmitters, emitters, receivers, detectors, etc.) in the lidar device while increasing the utilization of the remaining hardware to maintain performance levels. One approach to improving device reliability is to develop lidar devices that use fewer moving mechanical parts (e.g., by eliminating or simplifying mechanical beam scanners). One approach to extending range is to develop lidar devices that use solid-state lasers.

### Motivation for and Benefits of Some Embodiments

In a lidar device, each channel may be configured to operate in one more distinct modes, where the mode of operation determines the channel's resource utilization (e.g., electrical power consumed by the circuit that drives the channel's optical emitter) and characteristics of the optical signals emitted by the channel (e.g., the intensity, power level, or pulse width of the emitted optical signals). The characteristics of optical signals emitted by a channel can be determined by the amount of electrical current that passes through the channel's optical emitter when it emits the optical signals. The characteristics of emitted optical signals may be validated during a calibration process (e.g., performed during manufacturing of the lidar device).

During operation of a lidar device, the characteristics (e.g., power level, intensity, and/or time duration (e.g., pulse width)) of optical signals can vary from nominal (i.e., configured) values based on operating conditions, including the temperature of the lidar device and variation in the lidar device's electrical components. Further, during a lidar device's lifespan, a channel may degrade (e.g., due to excessive wear on the transmitter), such that the optical signals emitted by the degraded channel have altered characteristics (e.g., reduced power level, intensity, or pulse width) compared to the optical signals emitted by the channel during the calibration process, even if the degraded channel operates in the same mode used during the calibration process. Accordingly, as the actual characteristics of transmitted optical signals can differ from the nominal characteristics, miscalibration errors can be introduced into the processing of return signals reflected from objects in the lidar device's surrounding environment. Such errors can lead to inaccurate and/or otherwise misrepresented measurements of the properties (e.g., range, reflectivity, etc.) of objects in the surrounding environment.

Currently, a channel of a lidar device operating in a particular mode may be configured (e.g., during a calibration process) to emit an optical signal having one or more nominal characteristics. The one or more nominal characteristics may be functions of the electrical power provided to the channel's optical emitter when the channel operates in the particular operating mode. For example, the optical signal's nominal power level may be a function of the current that flows through the channel's emitter during the emission of the optical signal. But, due to variations in the operating conditions of a particular lidar device, the power level (and/or other characteristics) of an optical signal emitted by the channel may differ from the nominal power level (and/or other characteristics). These differences can result in errors while processing return signals from the surrounding environment, leading to inaccurate and/or otherwise misrepresented measurements of range and reflectivity of objects in the surrounding environment. Many existing lidar devices lack capabilities to measure and validate the characteristics (e.g., power level, intensity, time duration) of an emitted optical signal, instead measuring only the intensity of a return signal from objects in the surrounding environment. Accordingly, existing lidar devices are unable to compensate for variation from nominal optical characteristics by adjusting the electrical power used by a channel operating in a particular mode, resulting in inaccuracies in collected environmental data. Thus, there is a need for systems and methods of monitoring the characteristics (e.g., power levels) of optical signals emitted by a lidar device and for controlling the characteristics (e.g., power levels) of emitted optical signals by compensating for variation in the operation of the LIDAR device's components.

In response to the above-described limitations regarding monitoring and controlling power levels of emitted optical signals, circuitry for one or more transmitter power monitors (“TPMs”) may be added to a lidar device (e.g., to each channel of a lidar device) to monitor the power level(s) of emitted optical signals. In some cases, the TPM may be added to the circuitry corresponding to a channel's receiver during the fabrication of the channel's transmitter and receiver. A TPM may include one or more capacitors (e.g., capacitive loads) and may be configured to measure the electrical energy discharged from a capacitor to a lidar device's transmitter as the transmitter emits an optical signal. Based on the electrical energy discharged by the capacitor, the TPM can monitor the electrical energy dissipation of the circuit that drives the optical emitter and can thereby monitor the power levels of the emitted optical signals. The TPM may compare the measured electrical energy dissipation to a reference (e.g., nominal) electrical energy dissipation. Based on the comparison, the TPM may operate using closed loop control to adjust an operating parameter (e.g., a bias code) corresponding to the power applied to the lidar device's transmitter. Closed loop control of the transmitter's operating parameter may be used to compensate for a difference between the measured electrical energy dissipation and the reference electrical energy dissipation. An adjustment of the operating parameter may correspond to an increase or a decrease in the power applied to the transmitter, resulting in a corresponding increase or decrease in the power level of the transmitter's subsequent emitted optical signals. By adjusting the operating parameter, the measured power level (e.g., as indicated by the measured electrical energy dissipation) of the emitted optical signals may be maintained or restored within a threshold (e.g., range) corresponding to the nominal power level, such that performance of the lidar device is maintained and/or otherwise restored.

### Some Examples of Lidar Systems

A lidar system may be used to measure the shape and contour of the environment surrounding the system. Lidar systems may be applied to numerous applications including autonomous navigation and aerial mapping of surfaces. In general, a lidar system emits light that is subsequently reflected by objects within the environment in which the system operates. The light may be emitted by a laser (e.g., a rapidly firing laser). Laser light travels through a medium and reflects off points of surfaces in the environment (e.g., surfaces of buildings, tree branches, vehicles, etc.). The reflected (and/or scattered) light energy returns to a lidar detector where it may be sensed and used to perceive the environment.

The science of lidar systems is based on the physics of light and optics. Any suitable measurement techniques may be used to determine the attributes of objects in a lidar system's environment. In some examples, the lidar system is configured to emit light pulses (e.g., individual pulses or sequences of pulses). The time each pulse (or pulse sequence) travels from being emitted to being received (“time of flight” or “TOF”) may be measured to determine the distance between the lidar system and the object that reflects the pulse. Lidar systems that operate in this way may be referred to as “pulsed lidar,” “TOF lidar,” “direct TOF lidar,” or “pulsed TOF lidar.” In some other examples, the time of flight may be calculated indirectly (e.g., using amplitude-modulated continuous wave (AMCW) structured light). Lidar systems that operate in this way may be referred to as “indirect TOF lidar” or “iTOF lidar.” In still other examples, the lidar system can be configured to emit continuous wave (CW) light. The wavelength (or frequency) of the received, reflected light may be measured to determine the distance between the lidar system and the object that reflects the light. In some examples, lidar systems can measure the speed (or velocity) of objects. Lidar systems that operate in this way may be referred to as “coherent lidar,” “continuous wave lidar,” or “CW lidar.” In a CW lidar system, any suitable variant of CW lidar sensing may be used. For example, frequency modulated continuous wave (FMCW) lidar sensing may be used.

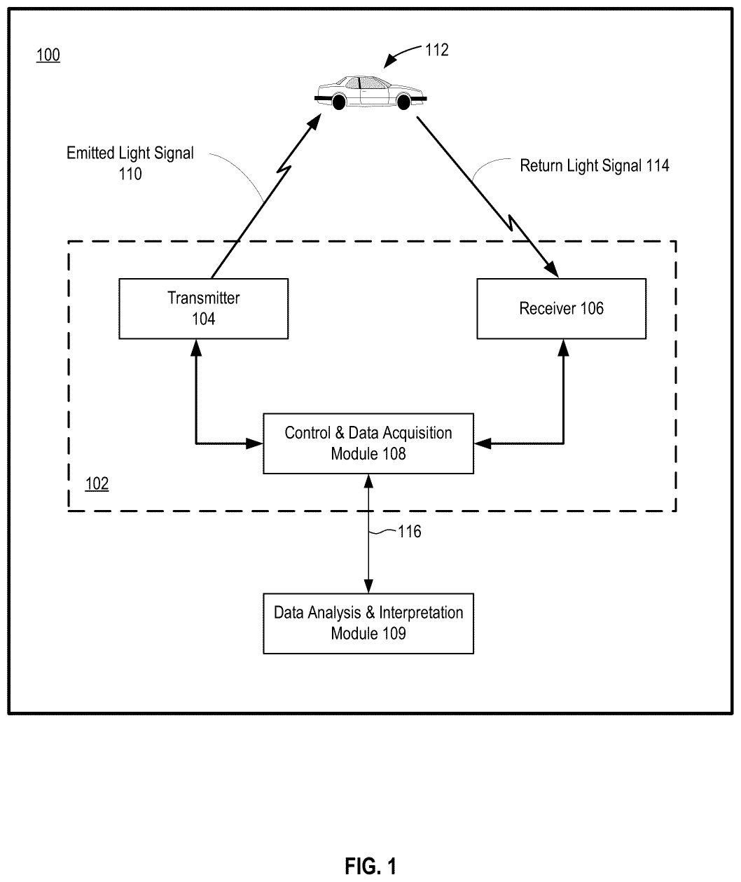

FIG. 1 depicts the operation of a lidar system 100, according to some embodiments. In the example of FIG. 1, the lidar system 100 includes a lidar device 102, which may include a transmitter 104 that generates and emits a light signal 110, a receiver 106 that detects and processes a return light signal 114, and a control & data acquisition module 108. The transmitter 104 may include a light source (e.g., “optical emitter” or “emitter”), electrical components operable to activate (e.g., drive) and deactivate the light source in response to electrical control signals, and optical components adapted to shape and redirect the light emitted by the light source. The receiver 106 may include a light detector (e.g., “optical detector,” “photodetector,” or “detector”) and optical components adapted to shape return light signals 114 and direct those signals to the detector. In some implementations, one or more optical components (e.g., lenses, mirrors, etc.) may be shared by the transmitter and the receiver.

The lidar device 102 may be referred to as a lidar transceiver or “channel.” In operation, the emitted light signal 110 propagates through a medium and reflects off an object(s) 112, whereby a return light signal 114 propagates through the medium and is received by receiver 106. In one example, each lidar channel may correspond to a physical mapping of a single emitter to a single detector (e.g., a one-to-one pairing of a particular emitter and a particular detector). In other examples, however, each lidar channel may correspond to a physical mapping of multiple emitters to a single detector or a physical mapping of a single emitter to multiple detectors (e.g., a “flash” configuration). In some examples, a lidar system 100 may have no fixed channels; rather, light emitted by one or more emitters may be detected by one or more detectors without any physical or persistent mapping of specific emitters to specific detectors.

Any suitable light source may be used including, without limitation, one or more gas lasers, chemical lasers, metal-vapor lasers, solid-state lasers (SSLs) (e.g., Q-switched SSLs, Q-switched solid-state bulk lasers, etc.), fiber lasers (e.g., Q-switched fiber lasers), liquid lasers (e.g., dye lasers), semiconductor lasers (e.g., laser diodes, edge emitting lasers (EELs), vertical-cavity surface emitting lasers (VCSELs), quantum cascade lasers, quantum dot lasers, quantum well lasers, hybrid silicon lasers, optically pumped semiconductor lasers, etc.), and/or any other device operable to emit light. For semiconductor lasers, any suitable gain medium may be used including, without limitation, gallium nitride (GaN), indium gallium nitride (InGaN), aluminum gallium indium phosphide (AlGaInP), aluminum gallium arsenide (AlGaAs), indium gallium arsenide phosphide (InGaAsP), lead salt, etc. For Q-switched lasers, any suitable type or variant of Q-switching can be used including, without limitation, active Q-switching, passive Q-switching, cavity dumping, regenerative Q-switching, etc. The light source may emit light having any suitable wavelength or wavelengths, including but not limited to wavelengths between 100 nm (or less) and 1 mm (or more). Semiconductor lasers operable to emit light having wavelengths of approximately 905 nm, 1300 nm, or 1550 nm are widely commercially available. In some examples, the light source may be operated as a pulsed laser, a continuous-wave (CW) laser, and/or a coherent laser. A light signal (e.g., “optical signal”) 110 emitted by a light source may consist of a single pulse, may include a sequence of two or more pulses, or may be a continuous wave.

A lidar system 100 may use any suitable illumination technique to illuminate the system's field of view (FOV). In some examples, the lidar system 100 may illuminate the entire FOV simultaneously. Such illumination techniques may be referred to herein as “flood illumination” or “flash illumination.” In some examples, the lidar system 100 may illuminate fixed, discrete spots throughout the FOV simultaneously. Such illumination techniques may be referred to herein as “fixed spot illumination.” In some examples, the lidar system 100 may illuminate a line within the FOV and use a scanner (e.g., a 1D scanner) to scan the line over the entire FOV. Such illumination techniques may be referred to herein as “scanned line illumination.” In some examples, the lidar system 100 may simultaneously illuminate one or more spots within the FOV and use a scanner (e.g., a 1D or 2D scanner) to scan the spots over the entire FOV. Such illumination techniques may be referred to herein as “scanned spot illumination.”

Any suitable optical detector may be used including, without limitation, one or more photodetectors, contact image sensors (CIS), solid-state photodetectors (e.g., photodiodes (PD), single-photon avalanche diode (SPADs), avalanche photodiodes (APDs), etc.), photomultipliers (e.g., silicon photomultipliers (SiPMs), and/or any other device operable to convert light (e.g., optical signals) into electrical signals. In some examples, CIS can be fabricated using a complementary metal-oxide semiconductor (CMOS) process. In some examples, solid-state photodetectors can be fabricated using semiconductor processes similar to CMOS. Such semiconductor processes may use silicon, germanium, indium gallium arsenide, lead (II) sulfide, mercury cadmium, telluride, MoS₂, graphene, and/or any other suitable material(s). In some examples, an array of integrated or discrete CIS or solid-state photodetectors can be used to simultaneously image (e.g., perform optical detection across) the lidar device's entire field of view or a portion thereof. In general, solid-state photodetectors may be configured to detect light having wavelengths between 190 nm (or lower) and 1.4 μm (or higher). PDs and APDs configured to detect light having wavelengths of approximately 905 nm, 1300 nm, or 1550 nm are widely commercially available.

The lidar system 100 may include any suitable combination of measurement technique(s), light source(s), illumination technique(s), and detector(s). Some combinations may be more accurate or more economical on certain conditions. For example, some combinations may be more economical for short-range sensing but incapable of provide accurate measurements at longer ranges. Some combinations may pose potential hazards to eye safety, while other combinations may reduce such hazards to negligible levels.

The control & data acquisition module 108 may control the light emission by the transmitter 104 and may record data derived from the return light signal 114 detected by the receiver 106. In some embodiments, the control & data acquisition module 108 controls the power level at which the transmitter 104 operates when emitting light. For example, the transmitter 104 may be configured to operate at a plurality of different power levels, and the control & data acquisition module 108 may select the power level at which the transmitter 104 operates at any given time. Any suitable technique may be used to control the power level at which the transmitter 104 operates. In some embodiments, the control & data acquisition module 108 or the receiver 106 determines (e.g., measures) particular characteristics of the return light signal 114 detected by the receiver 106. For example, the control & data acquisition module 108 or receiver 106 may measure the intensity of the return light signal 114 using any suitable technique.

Operational parameters of the transceiver 102 may include its horizontal field of view (“FOV”) and its vertical FOV. The FOV parameters effectively define the region of the environment that is visible to the specific lidar transceiver 102. More generally, the horizontal and vertical FOVs of a lidar system 100 may be defined by combining the fields of view of a plurality of lidar devices 102.

To obtain measurements of points in its environment and generate a point cloud based on those measurements, a lidar system 100 may scan its FOV. A lidar transceiver system 100 may include one or more beam-steering components (not shown) to redirect and shape the emitted light signals 110 and/or the return light signals 114. Any suitable beam-steering components may be used including, without limitation, mechanical beam steering components (e.g., rotating assemblies that physically rotate the transceiver(s) 102, rotating scan mirrors that deflect emitted light signals 110 and/or return light signals 114, etc.), optical beam steering components (e.g., lenses, lens arrays, microlenses, microlens arrays, beam splitters, etc.), microelectromechanical (MEMS) beam steering components (e.g., MEMS scan mirrors, etc.), solid-state beam steering components (e.g., optical phased arrays, optical frequency diversity arrays, etc.), etc.

In some implementations, the lidar system 100 may include or be communicatively coupled to a data analysis & interpretation module 109, which may receive outputs (e.g., via a connection 116) from the control & data acquisition module 108 and may perform data analysis on those outputs. By way of example and not limitation, connection 116 may be implemented using wired or wireless (e.g., non-contact communication) technique(s).

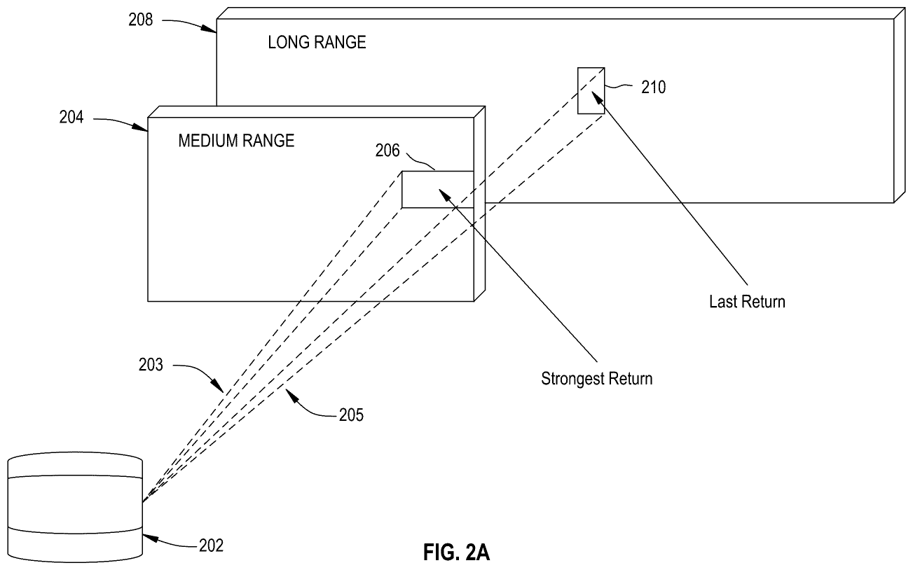

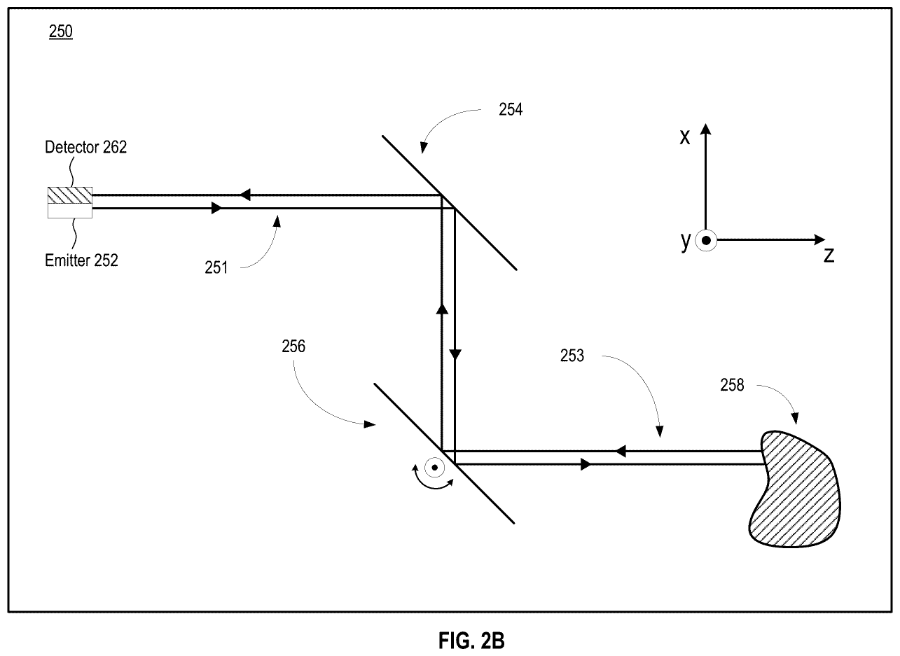

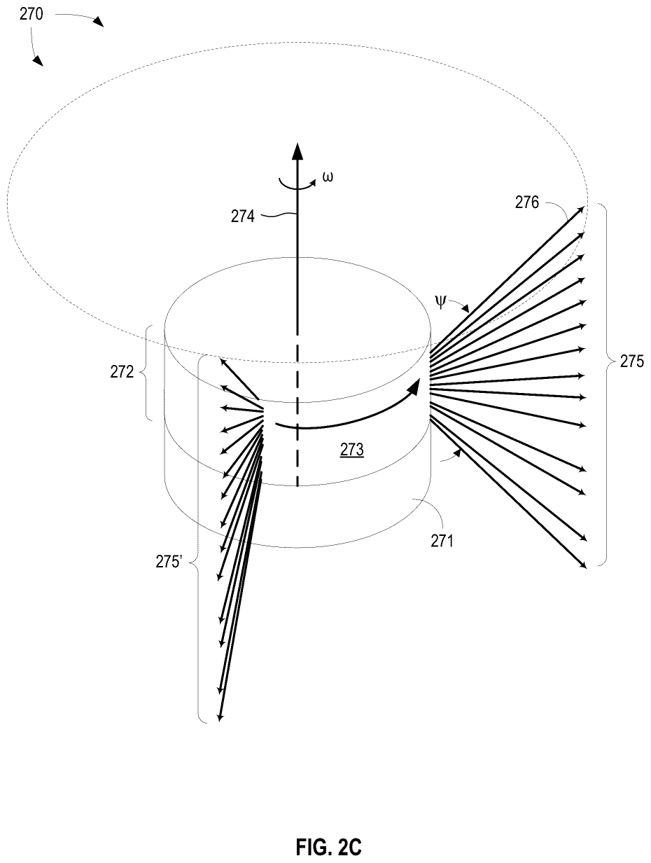

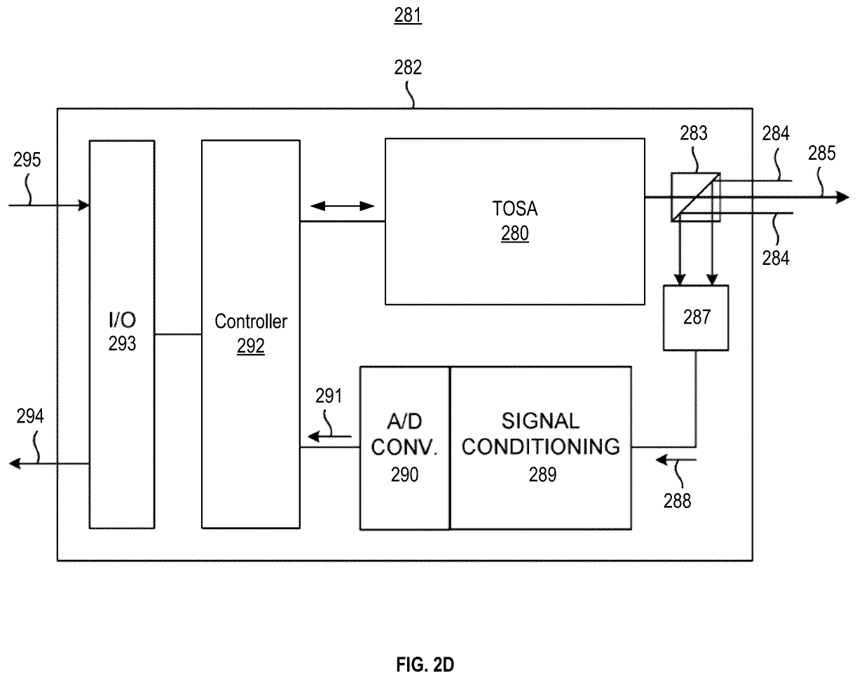

FIG. 2A illustrates the operation of a lidar system 202, in accordance with some embodiments. In the example of FIG. 2A, two return light signals 203 and 205 are shown. Because laser beams generally tend to diverge as they travel through a medium, a single laser emission may hit multiple objects at different ranges from the lidar system 202, producing multiple return signals 203, 205. The lidar system 202 may analyze multiple return signals 203, 205 and report one of the return signals (e.g., the strongest return signal, the last return signal, etc.) or more than one (e.g., all) of the return signals. In the example of FIG. 2A, lidar system 202 emits laser light in the direction of near wall 204 and far wall 208. As illustrated, the majority of the emitted light hits the near wall 204 at area 206 resulting in a return signal 203, and another portion of the emitted light hits the far wall 208 at area 210 resulting in a return signal 205. Return signal 203 may have a shorter TOF and a stronger received signal strength compared to return signal 205. In both single- and multiple-return lidar systems, it is important that each return signal is accurately associated with the transmitted light signal so that one or more attributes of the object reflecting the light signal (e.g., range, velocity, reflectance, etc.) can be correctly estimated.

Some embodiments of a lidar system may capture distance data in a two-dimensional (“2D”) (e.g., within a single plane) point cloud manner. These lidar systems may be used in industrial applications, or for surveying, mapping, autonomous navigation, and other uses. Some embodiments of these systems rely on the use of a single laser emitter/detector pair combined with a moving mirror to effect scanning across at least one plane. This mirror may reflect the emitted light from the transmitter (e.g., laser diode), and/or may reflect the return light to the receiver (e.g., to the detector). Use of a movable (e.g., oscillating) mirror in this manner may enable the lidar system to achieve 90-180-360 degrees of azimuth (horizontal) view while simplifying both the system design and manufacturability. Many applications require more data than just a 2D plane. The 2D point cloud may be expanded to form a 3D point cloud, in which multiple 2D point clouds are used, each corresponding to a different elevation (e.g., a different position and/or direction with respect to a vertical axis). Operational parameters of the receiver of a lidar system may include the horizontal FOV and the vertical FOV.

FIG. 2B depicts a lidar system 250 with a movable (e.g., rotating or oscillating) mirror, according to some embodiments. In the example of FIG. 2B, the lidar system 250 uses a single emitter 252/detector 262 pair combined with a fixed mirror 254 and a movable mirror 256 to effectively scan across a plane. Distance measurements obtained by such a system may be effectively two-dimensional (e.g., planar), and the captured distance points may be rendered as a 2D (e.g., single plane) point cloud. In some embodiments, but without limitation, the movable mirror 256 may oscillate at very fast speeds (e.g., thousands of cycles per minute).

The emitted laser signal 251 may be directed to a fixed mirror 254, which may reflect the emitted laser signal 251 to the movable mirror 256. As movable mirror 256 moves (e.g., oscillates), the emitted laser signal 251 may reflect off an object 258 in its propagation path. The reflected return signal 253 may be coupled to the detector 262 via the movable mirror 256 and the fixed mirror 254. In some embodiments, the movable mirror 256 is implemented with mechanical technology or with solid state technology (e.g., MEMS).

FIG. 2C depicts a 3D lidar system 270, according to some embodiments. In the example of FIG. 2C, the 3D lidar system 270 includes a lower housing 271 and an upper housing 272. The upper housing 272 includes a cylindrical shell element 273 constructed from a material that is transparent to infrared light (e.g., light having a wavelength within the spectral range of 700 to 1,700 nanometers). In one example, the cylindrical shell element 273 is transparent to light having wavelengths centered at 905 nanometers.

In some embodiments, the 3D lidar system 270 includes a lidar transceiver, such as transceiver 102 shown in FIG. 1, operable to emit laser beams 276 through the cylindrical shell element 273 of the upper housing 272. In the example of FIG. 2C, each individual arrow in the sets of arrows 275, 275′ directed outward from the 3D lidar system 270 represents a laser beam 276 emitted by the 3D lidar system. Each beam of light emitted from the system 270 (e.g., each laser beam 276) may diverge slightly, such that each beam of emitted light forms a cone of light emitted from system 270. In one example, a beam of light emitted from the system 270 illuminates a spot size of 20 centimeters in diameter at a distance of 100 meters from the system 270.

In some embodiments, the transceiver 102 emits each laser beam 276 transmitted by the 3D lidar system 270. The direction of each emitted beam may be determined by the angular orientation w of the transceiver's transmitter 104 with respect to the system's central axis 274 and by the angular orientation y of the transmitter's movable mirror (e.g., similar or identical to movable mirror 256 shown in FIG. 2B) with respect to the mirror's axis of oscillation (or rotation). For example, the direction of an emitted beam in a horizontal dimension may be determined by the transmitter's angular orientation @, and the direction of the emitted beam in a vertical dimension may be determined by the angular orientation y of the transmitter's movable mirror. Alternatively, the direction of an emitted beam in a vertical dimension may be determined the transmitter's angular orientation w, and the direction of the emitted beam in a horizontal dimension may be determined by the angular orientation y of the transmitter's movable mirror. (For purposes of illustration, the beams of light 275 are illustrated in one angular orientation relative to a non-rotating coordinate frame of the 3D lidar system 270 and the beams of light 275′ are illustrated in another angular orientation relative to the non-rotating coordinate frame.)

The 3D lidar system 270 may scan a particular point (e.g., pixel) in its field of view by adjusting the angular orientation w of the transmitter and the angular orientation y of the transmitter's movable mirror to the desired scan point (ω, ψ) and emitting a laser beam from the transmitter 104. Accordingly, the 3D lidar system 270 may systematically scan its field of view by adjusting the angular orientation w of the transmitter and the angular orientation y of the transmitter's movable mirror to a set of scan points (ωᵢ, ψⱼ) and emitting a laser beam from the transmitter 104 at each of the scan points.

Assuming that the optical component(s) (e.g., movable mirror 256) of a lidar transceiver remain stationary during the time period after the transmitter 104 emits a laser beam 110 (e.g., a pulsed laser beam or “pulse” or a CW laser beam) and before the receiver 106 receives the corresponding return beam 114, the return beam generally forms a spot centered at (or near) a stationary location L0 on the detector. This time period is referred to herein as the “ranging period” or “listening period” of the scan point associated with the transmitted beam 110 and the return beam 114.

In many lidar systems, the optical component(s) of a lidar transceiver do not remain stationary during the ranging period of a scan point. Rather, during a scan point's ranging period, the optical component(s) may be moved to orientation(s) associated with one or more other scan points, and the laser beams that scan those other scan points may be transmitted. In such systems, absent compensation, the location Li of the center of the spot at which the transceiver's detector receives a return beam 114 generally depends on the change in the orientation of the transceiver's optical component(s) during the ranging period, which depends on the angular scan rate (e.g., the rate of angular motion of the movable mirror 256) and the range to the object 112 that reflects the transmitted light. The distance between the location Li of the spot formed by the return beam and the nominal location L0 of the spot that would have been formed absent the intervening rotation of the optical component(s) during the ranging period is referred to herein as “walk-off.”

Referring to FIG. 2D, a block diagram of a transmitter-receiver optical subassembly (TROSA) 281 is shown, according to some embodiments. In some embodiments, the TROSA 281 may include a TOSA 280, an optical detector 287, a beam splitter 283, signal conditioning electronics 289, an analog to digital (A/D) converter 290, controller 292, and digital input/output (I/O) electronics 293. In some embodiments, the TROSA components illustrated in FIG. 2D are integrated onto a common substrate 282 (e.g., printed circuit board, ceramic substrate, etc.). In some embodiments, the TROSA components illustrated in FIG. 2D are individually mounted to a common substrate 282. In some embodiments, groups of these components are packaged together and the integrated package(s) is/are mounted to the common substrate.

The TOSA 280 may include one or more light sources and may operate the light source(s) safely within specified safety thresholds. A light source of the TOSA may emit an optical signal (e.g., laser beam) 285.

A return signal 284 may be detected by the TROSA 281 in response to the optical signal 285 illuminating a particular location. For example, the optical detector 287 may detect the return signal 284 and generate an electrical signal 288 based on the return signal 284. The controller 292 may initiate a measurement window (e.g., a period of time during which collected return signal data are associated with a particular emitted light signal 285) by enabling data acquisition by optical detector 287. Controller 292 may control the timing of the measurement window to correspond with the period of time when a return signal is expected in response to the emission of an optical signal 285. In some examples, the measurement window is enabled at the time when the optical signal 285 is emitted and is disabled after a time period corresponding to the time of flight of light over a distance that is substantially twice the range of the lidar device in which the TROSA 281 operates. In this manner, the measurement window is open to collect return light from objects adjacent to the lidar device (e.g., negligible time of flight), objects that are located at the maximum range of the lidar device, and objects in between. In this manner, other light that does not contribute to a useful return signal may be rejected.

In some embodiments, the signal analysis of the electrical signal 288 produced by the optical detector 287 is performed by the controller 292, entirely. In such embodiments, the signals 294 provided by the TROSA 281 may include an indication of the distances determined by controller 292. In some embodiments, the signals 294 include the digital signals 291 generated by the A/D converter 290. These raw measurement signals 291 may be processed further by one or more processors located on board the lidar device or external to the lidar device to arrive at a measurement of distance. In some embodiments, the controller 292 performs preliminary signal processing steps on the signals 291 and the signals 294 include processed data that are further processed by one or more processors located on board the lidar device or external to the lidar device to arrive at a measurement of distance.

In some embodiments a lidar device (e.g., a lidar device 100, 202, 250, or 270) includes multiple TROSAs 281. In some embodiments, a delay time is enforced between the firing of each TROSA and/or between the firing of different light sources within the same TROSA. In some examples, the delay time is greater than the time of flight of the light signal 285 to and from an object located at the maximum range of the lidar device, to reduce or avoid optical cross-talk among any of the TROSAs 281. In some other examples, an optical signal 285 is emitted from one TROSA 281 before a return signal corresponding to a light signal emitted from another TROSA 281 has had time to return to the lidar device. In these embodiments, there may be sufficient spatial separation between the areas of the surrounding environment interrogated by the light signals of these TROSAs to avoid optical cross-talk.

In some embodiments, digital I/O 293, A/D converter 290, and signal conditioning electronics 289 are integrated onto a single, silicon-based microelectronic chip. In another embodiment, these same elements are integrated into a single gallium-nitride or silicon based circuit that also includes components of the TOSA 280 (e.g., an illumination driver). In some embodiments, the A/D converter 290 and controller 292 are combined as a time-to-digital converter.

As depicted in FIG. 2D, return light 284 reflected from the surrounding environment is detected by optical detector 287. In some embodiments, optical detector 287 includes one or more avalanche photodiodes (APDs) and/or single-photon avalanche diodes (SPADs). Any suitable optical detector may be used. In some embodiments, optical detector 287 generates an output signal 288 that is amplified by signal conditioning electronics 289. In some embodiments, signal conditioning electronics 289 include an analog trans-impedance amplifier. However, in general, the amplification of output signal 288 may include multiple amplifier stages. In this sense, an analog transimpedance amplifier is provided by way of non-limiting example, as many other analog signal amplification schemes may be used.

In some embodiments, the amplified signal is communicated to A/D converter 290, and the digital signals generated by the A/D converter are communicated to controller 292. Controller 292 may generate an enable/disable signal to control the timing of data acquisition by ADC 290.

As depicted in FIG. 2D, the optical signal 285 emitted from the TROSA 281 and the return signal 284 directed toward the TROSA 281 share a common path within the lidar device. In the embodiment depicted in FIG. 2D, the return light 284 is separated from the emitted light 285 by a beam splitter 283. The beam splitter may direct the light 285 emitted by the TOSA 280 toward the lidar device's environment, and direct the return light 284 to the optical detector 287. Any suitable beam splitter may be used, including (without limitation) a polarizing beam splitter, nonpolarizing beam splitter, dielectric film, etc.). Some non-limiting examples of suitable beam splitters are described in International Patent Publication No. WO 2017/164989.

### Power Monitoring Circuitry

As described herein, power levels of emitted optical signals of a lidar device may vary from nominal levels based on changes in the device's operating conditions. Some examples of changes in operation conditions include degradation of the lidar device over time, changes in the lidar device temperature (e.g., due to environmental conditions of the surrounding environment), and variation (e.g., manufacturing tolerance variation) in the device's electrical components. Accordingly, there exists a need for systems and methods to monitor and control the power levels of emitted optical signals to compensate for changes in the lidar device's operating conditions and maintain adequate device performance (e.g., range and intensity detection).

In some embodiments, a TPM included in a PCM is used to measure power levels of optical signals emitted by a channel's transmitter. The TPM may measure an indication of a power level of an emitted optical signal by measuring energy dissipated through the transmitter during optical signal emission. Energy dissipated through the transmitter may be stored in one or more capacitors included in the TPM. The PCM may include a logic module configured to sample the energy stored by the TPM to determine an energy dissipation value indicative of a measured power level of the emitted optical signal. The logic module may compare the energy dissipation value to a nominal energy dissipation value. Based on the comparison, the logic module may determine whether to maintain or adjust (e.g., increase or decrease) an operating parameter corresponding to the power applied to the channel's transmitter for a particular operating mode.

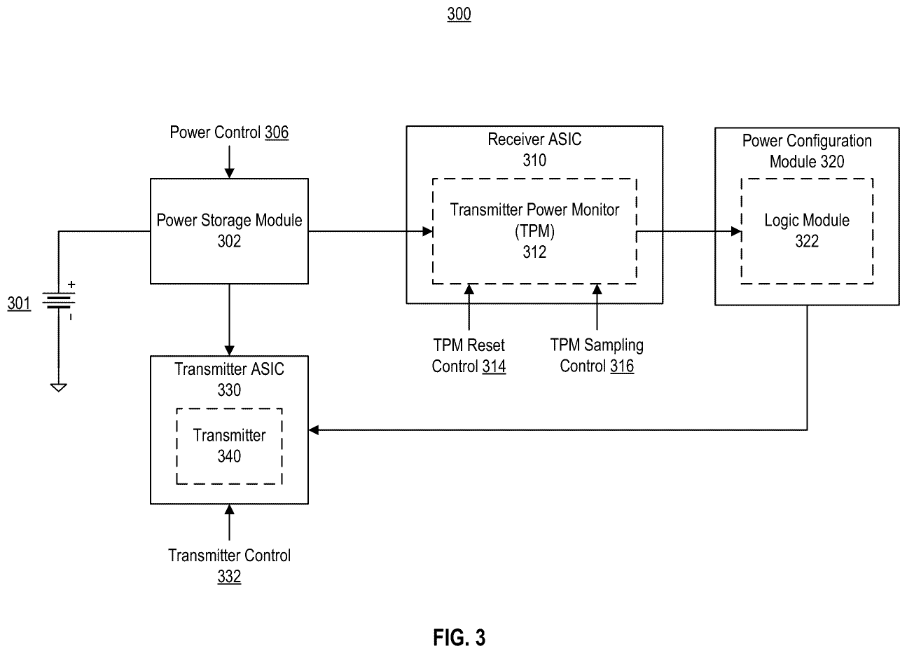

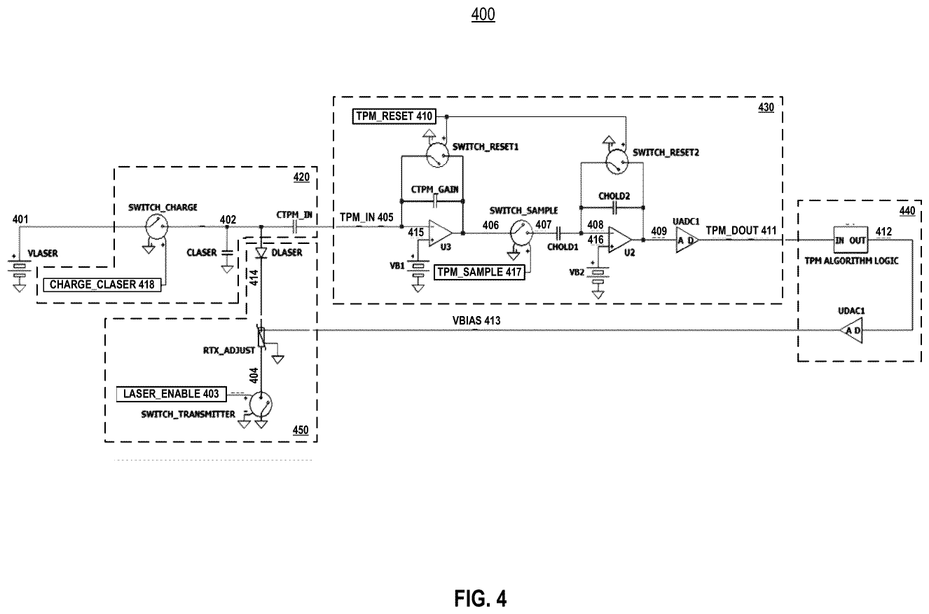

FIG. 3 shows a block diagram of a PCM 300 in a lidar device, according to some embodiments. The PCM 300 may include a power storage module 302, a receiver application specific integrated circuit (“ASIC”) 310 that includes a TPM 312, a power configuration module 320, a transmitter ASIC 330, and/or a transmitter 340, which each may be electrically coupled (e.g., as shown in FIG. 3). A power supply 301 may supply an electrical signal (e.g., power) to the power storage module 302. The power supply 301 may be internal or external to the PCM 300. As an example, the power supply 301 may be a voltage source. The power supply 301 may supply the necessary power to charge a capacitor (not shown in FIG. 3) included in the power storage module 302, where the capacitor can be discharged to cause the transmitter 340 to emit an optical signal (e.g., as described with respect to FIG. 4).

In some embodiments, a lidar device includes one or more transmitter-receiver optical sub-assemblies (“TROSAs”) 281, where each TROSA may correspond to one or more channels of a lidar device. A TROSA may include at least once receiver ASIC and at least one transmitter ASIC. Any suitable number of TROSAs of a lidar device may include a PCM 300 as described herein. The PCM 300 may be integrated and/or otherwise included with one or more components of a TROSA. For example, the PCM 300 may be integrated with the circuitry corresponding to a transmitter and a receiver of a TROSA.

In some embodiments, a power control signal 306 can be enabled (e.g., activated) or disabled (e.g., deactivated) to provide power or not provide power to a power source (e.g., capacitor) included in the power storage module 302. The power source of the power storage module 302 may provide an electrical signal (e.g., current) to the transmitter 340. By activating the power control signal 306, the power source of the power storage module 302 can charge to a voltage provided by the power supply 301. By deactivating the power control signal 306, the power source of the power storage module 302 cannot be charged by the power supply 301.

As shown in FIG. 3, the power storage module 302 may be coupled to the receiver ASIC 310 and the TPM 312, where the receiver ASIC 310 includes the TPM 312. In some cases, the TPM 312 is included in the receiver ASIC 310 based on the fabrication process of the transmitter ASIC 330 and the receiver ASIC 310. As an example, the transmitter ASIC 330 may be fabricated using a gallium nitride (GaN) fabrication process and the receiver ASIC 310 may be fabricated using a silicon fabrication process. Based on the TPM 312 being more reliably and/or easily fabricated using a silicon process, the TPM 312 may be included in the receiver ASIC 310 (rather than in the transmitter ASIC 330). The TPM 312 may be fabricated using any suitable technique and may have any suitable position and location within the PCM 300. In some cases, the receiver ASIC 310 includes the TPM 312 based on the respective voltage domains of the transmitter ASIC 330 and the receiver ASIC 310. As an example, the transmitter ASIC 330 may operate using a high voltage domain (e.g., 10-100 V) and the receiver ASIC 310 may operate using a low voltage domain (e.g., 3-30 V). Based on the TPM 312 being configured to operate with a low voltage domain, the receiver ASIC 310 (rather than in the transmitter ASIC 330) may include the TPM 312. The TPM 312 may be configured for any suitable voltage domain within the PCM 300.

In some embodiments, the TPM 312 is coupled to the power storage module 302 and the power configuration module 320. The TPM 312 may include one or more operational amplifiers, converters (e.g., digital to analog and/or analog to digital converters), power sources, switches, and loads (e.g., capacitors) that can be used to measure and/or otherwise store the electrical energy dissipated through the transmitter 340 (e.g., by discharging a capacitor of the power storage module 302 through the transmitter 340).

In some cases, a TPM reset control signal 314 may be enabled or disabled to respectively reset or not reset monitoring, by the TPM module 312, of the energy dissipated by the transmitter 340. By activating the TPM reset control signal 314, one or more capacitors (described further with respect to FIG. 4) of the TPM module 312 may discharge to baseline, reference voltage levels. As an example, by activating the TPM reset control signal 314, capacitor(s) of the TPM module 312 may discharge, such that they are not representative of the energy dissipated by the transmitter 340 during the emission of an optical signal. By deactivating the TPM reset control signal 314, the one or more capacitors of the TPM module 312 may be able to charge to a particular voltage and store electrical energy that is representative of the energy dissipation through the transmitter 340. As an example, the one or more capacitors of the TPM module 312 may charge to a voltage representative of the change in voltage of a capacitor of the power storage module 302 during the emission of an optical signal by the transmitter 340.

In some cases, a TPM sampling control signal 316 may be enabled or disabled to respectively enable or disable storage and measurement of the energy dissipated through the transmitter 340 (e.g., to determine a power level of the emitted optical signal). By activating the TPM sampling control signal 316, the one or more capacitors of the TPM module 312 may be able to charge to a particular voltage and store electrical energy that is representative of the energy dissipation through the transmitter 340. By deactivating the TPM sampling control signal 316, the one or more capacitors of the TPM module 312 may maintain a stored voltage, such that the stored voltage may be measured and/or otherwise sampled by the power configuration module 320. The TPM sampling control signal 316 may be required to be enabled for the power configuration module 320 to correctly determine the energy dissipation through the transmitter 340 (and the corresponding optical power level).

In some embodiments, the power configuration module 320 is coupled to the TPM 312 of the receiver ASIC 310 and to the transmitter ASIC 330. In some cases, the power configuration module 320 may include a logic module 322 configured to measure and/or sample a voltage output (e.g., a digital voltage output) provided by the TPM 312. The voltage output measured by the logic module 322 of the power configuration module 320 may be indicative of the electrical energy dissipated through the transmitter 340 and the power level of the emitted optical signal. Based on the measured voltage output, the logic module 322 may determine whether to maintain or adjust (e.g., increase or decrease) the power (e.g., control voltage) applied to the transmitter 340. The logic module 322 may control the power applied to the transmitter 340 by maintaining or adjusting an operating parameter (e.g., bias code) corresponding to a control voltage to be applied to the transmitter ASIC 330 (as described further with respect to FIG. 4). One or more nominal control voltages may be initially configured for the PCM 300 of the lidar device during a calibration method, where each nominal control voltage corresponds to an operating mode of the lidar device and where the transmitter 340 may be configured to emit optical signals at any of the nominal control voltages during an operating period (e.g., a period where the lidar device collects environmental range and intensity data). A control voltage applied to the transmitter ASIC 330 may correspond to an operating parameter (e.g., bias code), where each respective control voltage corresponds to a unique operating parameter. The logic module 322 may be configured to initialize a control voltage for controlling the optical power of the transmitter 340 before it emits an optical signal. After measuring the voltage output from the TPM 312, the logic module 322 may maintain or adjust the control voltage applied to the transmitter ASIC 330 (e.g., via the operating parameter) using closed loop control techniques as described below. One or more unique operating parameters corresponding to respective control voltages may be stored by a memory device of the lidar device. The one or more unique operating parameters corresponding to respective control voltages may be accessed by and/or included with the logic module 322.

In some embodiments, the transmitter ASIC 330 is coupled to the power configuration module 320 and to the transmitter 340. The transmitter ASIC 330 may include a variable resistor (e.g., a voltage-controlled resistor) coupled to the transmitter 340. The resistance of the variable resistor may be configured by a control voltage (e.g., a bias voltage applied to the resistor), where the power configuration module 320 provides the control voltage to the variable resistor. The resistance of the variable resistor may control the amount of current that may pass through the transmitter 340, where the power level of an emitted optical signal is a function of the magnitude of the current passing through the transmitter 340. For example, the power level of an emitted optical signal may be proportional to the magnitude of the current flowing through the transmitter 340. A transmitter control signal 332 may be enabled or disabled to respectively allow or impede the passage of current through the transmitter 340. The transmitter control signal 332 may be coupled to a switch in the transmitter ASIC 330, where the position (e.g., connected or disconnected) of the switch controls whether current can pass through the transmitter 340. When current passes through the transmitter 340, the transmitter 340 may emit an optical signal. The transmitter 340 may emit an optical signal for a duration that current passes through the transmitter 340. To emit an optical pulse, the transmitter control signal 332 may be enabled and then disabled after a duration of time, where the duration of time defines the pulse width of the optical pulse. By activating the transmitter control signal 332, a current (e.g., discharging from a charged capacitor of the power storage module 302) can pass through the transmitter 340, thereby causing the transmitter 340 to emit an optical signal. By deactivating the transmitter control signal 332, a current cannot pass not through the transmitter 340, thereby causing the transmitter 340 to cease emission of the optical signal.

### Configuration for Power Monitoring and Control

As described herein, a PCM may be integrated with a lidar device and may measure the power levels of optical signals emitted by the channel's transmitter. The PCM may measure the power level of an emitted optical signal by measuring the energy dissipated through the channel's transmitter during the emission of the optical signal. In some cases, a change in voltage of a power source (e.g., capacitor) coupled to the transmitter can indicate an amount of energy dissipated through the channel's transmitter. As an example, based on enabling a signal (e.g., transmitter control signal 332), a capacitor coupled to the transmitter may discharge and cause current to pass from the capacitor through the transmitter, thereby causing the transmitter to emit an optical signal. A PCM may be configured with one or more components as described herein (e.g., for FIG. 3). FIG. 4 depicts an exemplary circuit of a PCM 400 in a lidar device. The PCM 400 may include a power storage module 420, a TPM 430 (e.g., included in a receiver ASIC 310), a power configuration module 440, and a transmitter ASIC 450. In some cases, the power storage module 420, the TPM 430, the power configuration module 440, and the transmitter ASIC 450 depicted in FIG. 4 correspond to the power storage module 302, the TPM 312, the power configuration module 320, and the transmitter ASIC 330, respectively, depicted in FIG. 3. The PCM 400 may also include and/or otherwise be coupled to a power supply VLASER with first (e.g., positive) and second (e.g., negative) terminals. The first terminal of the power supply VLASER may be coupled to a first end of a switch SWITCH_CHARGE included in the power storage module 420. The power supply VLASER may provide a voltage at node 401 as shown in FIG. 4.

In some embodiments, in addition to the configurable switch SWITCH_CHARGE, the power storage module 420 includes a first capacitor CLASER and a second capacitor CTPM_IN. The switch SWITCH_CHARGE may be configured as connected (e.g., closed) or disconnected (e.g., open) by the external connection CHARGE_CLASER 418. As an example, the external connection CHARGE_CLASER 418 may correspond to the power control signal 306 described herein with respect to FIG. 3. If the external connection CHARGE_CLASER 418 is activated and/or otherwise enabled, the switch SWITCH_CHARGE may be connected (e.g., closed). If the external connection CHARGE_CLASER 418 is deactivated and/or otherwise disabled, the switch SWITCH_CHARGE may be disconnected (e.g., open). The node 402 does not charge to the voltage of node 401 (e.g., provided by the power supply VLASER) if the switch SWITCH_CHARGE is disconnected. A second end of the switch SWITCH_CHARGE, the capacitor CLASER, and the capacitor CTPM_IN may be coupled at node 402 as shown in FIG. 4. The node 402 charges to the voltage of node 401 (e.g., provided by the power supply VLASER) if the switch SWITCH_CHARGE is connected. In some cases, an anode of a laser diode DLASER of the transmitter ASIC 450 is also coupled to the node 402, as shown in FIG. 4. As an example, the laser diode DLASER may correspond to the transmitter 340 described herein with respect to FIG. 3.

In some embodiments, the capacitor CTPM_IN of the power storage module 420 is coupled to an input of the TPM 430. The TPM 430 may include power supplies VB1 and VB2 that each have first (e.g., positive) and second (e.g., negative) terminals. The TPM 430 may also include one or more capacitors. The one or more capacitors may include capacitors CTPM_GAIN, CHOLD1, and CHOLD2 as shown in FIG. 4. The TPM 430 may also include configurable switches SWITCH_RESET1, SWITCH_RESET2, and SWITCH_SAMPLE. The TPM 430 may further include operational amplifiers U3 and U2 that each have first (e.g., positive), second (e.g., negative), and third (e.g., output) terminals. The TPM 430 may also include an analog to digital converter (e.g., voltage converter) UADC1 that includes first (e.g., input) and second (e.g., output) terminals. The analog to digital converter UADC1 may be configured to convert an analog voltage input to a digital voltage output.

In some embodiments, the switches SWITCH_RESET1 and SWITCH_RESET2 are each configured as connected (e.g., closed) or disconnected (e.g., open) by the external connection TPM_RESET 410. As an example, the external connection TPM_RESET 410 may correspond to the TPM reset control signal 314 described herein with respect to FIG. 3. If the external connection TPM_RESET 410 is activated and/or otherwise enabled, the switches SWITCH_RESET1 and SWITCH_RESET2 may be connected (e.g. closed). In some cases, the capacitors CTPM_GAIN, CHOLD1, and CHOLD2 discharge to a baseline voltage (e.g., 0 V) if the external connection TPM_RESET 410 is enabled. If the external connection TPM_RESET 410 is deactivated and/or otherwise disabled, the switches SWITCH_RESET1 and SWITCH_RESET2 may be disconnected (e.g., opened). In some cases, the capacitors CTPM_GAIN, CHOLD1, and CHOLD2 charge to one or more voltages if the external connection TPM_RESET 410 is disabled.

In some embodiments, the capacitor CTPM_IN, a negative terminal of the operational amplifier U3, the capacitor CTPM_GAIN, and the switch SWITCH_RESET1 are coupled at node TPM IN 405 as shown in FIG. 4. A positive terminal of the power supply VB1 and a positive terminal of the operational amplifier U3 may be coupled at node 415. The capacitor CTPM_GAIN, the switch SWITCH_RESET1, an output terminal of the operational amplifier U3, and the switch SWITCH_SAMPLE may be coupled at node 406 as shown in FIG. 4. The switch SWITCH_SAMPLE may be configured as connected (e.g., closed) or disconnected (e.g., open) by an external connection TPM_SAMPLE 417. As an example, the external connection TPM_SAMPLE 417 may correspond to the TPM sampling control signal 316 described herein with respect to FIG. 3. If the external connection TPM_SAMPLE 417 is activated and/or otherwise enabled, the switch SWITCH_SAMPLE may be connected (e.g., closed). In some cases, the capacitors CHOLD1 and CHOLD2 charge to one or more voltages (e.g., corresponding to the energy dissipation of the capacitor CLASER) if the external connection TPM_SAMPLE 417 is enabled. As an example, the capacitors CHOLD1 and CHOLD2 may charge to voltages representative of the energy dissipation of the laser diode DLASER, which may indicate the power level of an optical signal emitted by the laser diode DLASER. If the external connection TPM_SAMPLE 417 is deactivated and/or otherwise disabled, the switch SWITCH_SAMPLE may be disconnected (e.g., opened). In some cases, the capacitors CHOLD1 and CHOLD2 do not discharge, but instead maintain one or more voltages if the external connection TPM_SAMPLE 417 is disabled.

In some embodiments, the switch SWITCH_SAMPLE is coupled to the capacitor CHOLD1 at node 407 as shown in FIG. 4. The capacitor CHOLD1, a negative terminal of the operational amplifier U2, the capacitor CHOLD2, and the switch SWITCH_RESET2 may be coupled at node 408 as shown in FIG. 4. A positive terminal of the power supply VB2 and a positive terminal of the operational amplifier U2 may be coupled at node 416. An output terminal of the operational amplifier U2, the capacitor CHOLD2, the switch SWITCH_RESET2, and an input terminal of the analog to digital converter UADC1 may be coupled at node 409 as shown in FIG. 4. An output terminal of the analog to digital converter UADC1 may be coupled to an input terminal of a logic module TPM ALGORITHM LOGIC at node TPM_DOUT 411 as shown in FIG. 4, where the logic module TPM ALGORITHM LOGIC is included in the power configuration module 440. The logic module TPM ALGORITHM LOGIC may correspond to the logic module 322 as described herein with reference to FIG. 3. An analog voltage input at node 409 may be converted to a digital voltage output by the analog to digital converter UADC1, such that the digital voltage output is provided to the logic module TPM ALGORITHM LOGIC at the node TPM_DOUT 411. The digital voltage output may be representative of the energy dissipation through the laser diode DLASER and the power level of an optical signal emitted by the laser diode DLASER.

In some embodiments, the power configuration module 440 includes the logic module TPM ALGORITHM LOGIC as described herein, where an input of the logic module TPM ALGORITHM LOGIC is coupled to the node 411. The power configuration module 440 may also include a digital to analog converter UDAC1 that includes first (e.g., input) and second (e.g., output) terminals. In some cases, the logic module TPM ALGORITHM LOGIC determines whether to modify a control voltage provided to a variable resistor RTX_ADJUST based on the digital voltage output at the node TPM_DOUT 411. An output of the logic module TPM ALGORITHM LOGIC may be coupled to an input terminal of the digital to analog converter UDAC1 at node 412 as shown in FIG. 4. The logic module TPM ALGORITHM LOGIC may determine an operating parameter (e.g., bias code) corresponding to a particular control voltage based on the digital voltage output at the node TPM_DOUT 411. The logic module TPM ALGORITHM LOGIC may provide a digital output indicative of the determined operating parameter to the digital to analog converter UDAC1. The logic module TPM ALGORITHM LOGIC may adjust or maintain the operating parameter based on the digital voltage output received from the analog to digital converter UADC1. An output of the digital to analog converter UDAC1 may be coupled to the variable resistor RTX_ADJUST at node VBIAS 413 as shown in FIG. 4. The digital to analog converter UDAC1 may be configured to convert a digital output provided by the logic module TPM ALGORITHM LOGIC to an analog voltage (e.g., control voltage) that can configure the resistance of variable resistor RTX_ADJUST of the transmitter ASIC 450 as described herein.

In some embodiments, the transmitter ASIC 450 includes the variable resistor RTX_ADJUST, the laser diode DLASER, and a configurable switch SWITCH_TRANSMITTER. The output of the digital to analog converter UDAC1 may be coupled to the variable resistor RTX_ADJUST at the node VBIAS 413. The voltage at the node VBIAS 413 may be a control voltage determined by the logic module TPM ALGORITHM LOGIC that is configured to control (e.g., adjust or maintain) the resistance of the variable resistor RTX_ADJUST. The variable resistor RTX_ADJUST and a cathode of the laser diode DLASER may be coupled at node 414 as shown in FIG. 4. The laser diode DLASER may be configured to emit an optical signal for a time period during which current passes through the laser diode DLASER, where the power level of the optical signal corresponds to (e.g., depends on) the magnitude of the current. The configured resistance of the variable resistor RTX_ADJUST may determine the magnitude of the current that may pass through the laser diode DLASER, such that the configured resistance determines the power level of an optical signal emitted by the laser diode DLASER.

In some embodiments, the variable resistor RTX_ADJUST is coupled to the switch SWITCH_TRANSMITTER at the node 404. The switch SWITCH_TRANSMITTER may be configured as connected (e.g., closed) or disconnected (e.g., open) by an external connection LASER_ENABLE 403. As an example, the external connection LASER_ENABLE 403 may correspond to the transmitter control signal 332 described herein with reference to FIG. 3. If the external connection LASER_ENABLE 403 is activated and/or otherwise enabled, the switch SWITCH_TRANSMITTER may be connected (e.g., closed). In some cases, the capacitor CLASER may discharge and a current may pass through the laser diode DLASER, the variable resistor RTX_ADJUST, and the switch SWITCH_TRANSMITTER if the switch SWITCH_TRANSMITTER is connected (e.g., by activating the external connection LASER_ENABLE 403). As an example, the laser diode DLASER may emit an optical signal if the external connection LASER_ENABLE 403 is enabled and the capacitor CLASER is charged to a suitable voltage. If the external connection LASER_ENABLE 403 is deactivated and/or otherwise disabled, the switch SWITCH_TRANSMITTER may be disconnected (e.g., open). In some cases, the capacitor CLASER does not discharge, but instead maintains a voltage (e.g., the voltage at node 401) if the external connection LASER_ENABLE 403 is disabled. As an example, the laser diode DLASER does not emit an optical signal if the external connection LASER_ENABLE 403 is disabled. For the lidar device to emit an optical pulse (e.g., for environmental data collection), the external connection LASER_ENABLE 403 may be enabled and then disabled for a configured duration of time corresponding to the pulse width of the optical pulse. The energy dissipated by the capacitor CLASER may be represented by Equation 1 as follows:

$$E = {C ( Δ V )}^{2} \qquad Equation 1$$

As shown in Equation 1, E is the energy dissipated by the capacitor CLASER during the emission of an optical signal (e.g., as controlled by the external connection LASER_ENABLE 403), C is the capacitance of the capacitor CLASER, and ΔV is a change in voltage of the capacitor CLASER during the emission of the optical signal (e.g., optical pulse). The energy dissipated by the capacitor may be monitored by components of the TPM 430, such that the capacitors of the TPM 430 store voltages that may be sampled and/or otherwise measured by the power configuration module 440 to determine the power level of an emitted optical signal. Based on determining the power level of an emitted optical signal (e.g., as indicated by the digital voltage output at the node TPM_DOUT 411), the power configuration module 440 may use control techniques (e.g., closed-loop control techniques) to determine whether to adjust (e.g., increase or decrease) or maintain an operating parameter corresponding to the control voltage applied to the variable resistor RTX_ADJUST (e.g., at the node VBIAS 413) to compensate for variation from a nominal power level.

### Method for Monitoring and Controlling Optical Power

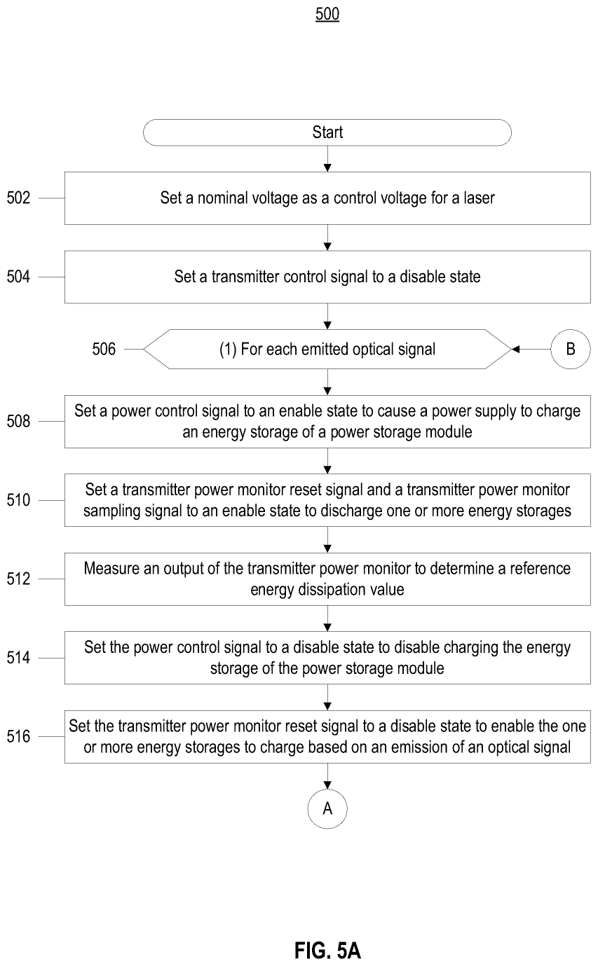

In some embodiments, to measure and control the power levels of optical signals emitted by a particular transmitter of a lidar device, a PCM (e.g., PCM 300 or 400) operates according to a power monitoring and control method. FIGS. 5A and 5B show a flowchart of an example method 500 for monitoring and controlling optical power at a lidar device. A PCM (e.g., PCM 300 or 400) may be used to monitor and control optical power at a lidar device. The method 500 may be suitable for measuring the power level of an emitted optical signal and controlling an operating parameter of the transmitter (e.g., the control voltage applied to the transmitter), thereby controlling the power level of one or more subsequent emitted optical signals to target a nominal power level. The method 500 may be performed individually for each channel of a lidar device that includes a PCM. As indicated by the loop header 506, steps 508-528 of the method 500 may be performed for each optical signal emitted by the channel of the lidar device. For simplicity, the following paragraphs describe steps 508-528 with reference a single channel of the lidar device emitting a single optical signal. However, one of ordinary skill in the art will appreciate that steps 508-528 may be performed repeatedly for each optical signal emitted by the channel. The method 500 may be executed by components of the PCM (e.g., PCM 300 and/or 400), a control module (e.g., control and data acquisition module 108), a data analysis module (e.g., data analysis and interpretation module 109), and/or any other suitable controller of the lidar device. For example, the control and data acquisition module 108 may configure one or more control signals (e.g., the control signals described with respect to FIGS. 3 and/or 4) for the PCM. In some cases, the method 500 may be configured to execute for each nominal power level (e.g., control voltage) of a channel of the lidar device.

At step 502, a logic module (e.g., logic module 322 or logic module TPM ALGORITHM LOGIC) of a power configuration module (e.g., power configuration module 320 or power configuration module 440) may set and/or otherwise configure a nominal voltage as a control voltage for a transmitter (e.g., laser) of a lidar device. In some cases, the logic module may receive instructions from a controller to configure the control voltage. The logic module may set a nominal voltage as the control voltage based on the nominal voltage corresponding to an operating mode of the lidar device, where the nominal voltage corresponding to the operating mode is stored by a memory device of the lidar device. The nominal voltage may be a calibrated voltage determined during a calibration method for the lidar device under nominal operating conditions. The nominal control voltage may correspond to a respective nominal energy dissipation value indicative of the energy dissipated through the laser during an emission of an optical signal under nominal operating conditions. Each nominal energy dissipation value may correspond to an operating mode of the lidar device under nominal operating conditions. For example, the nominal energy dissipation value may be measured during a calibration operation of the lidar device during a manufacturing process. As described herein, a measured energy dissipation value for the nominal control voltage may vary from the nominal energy dissipation value based on changes to the operating conditions of the lidar device. To set the nominal voltage, the logic module may determine an operating parameter (e.g., bias code) corresponding to the nominal voltage to be applied to a transmitter of the lidar device. The logic module may provide an indication of the determined operating parameter to a digital to analog converter (e.g., digital to analog converter UDAC1) of the power configuration module, which may determine and output the nominal voltage corresponding to the operating parameter. The digital to analog converter may output the nominal voltage to the node VBIAS 413 as shown in FIG. 4, thereby configuring the resistance of the variable resistor RTX_ADJUST. In some cases, if the control voltage for an operating mode of the lidar device was previously adjusted from the nominal voltage, the logic module may set and/or otherwise configure the adjusted control voltage as the control voltage for a transmitter (e.g., laser) of a lidar device at step 502.

At step 504, a controller may set a transmitter control signal (e.g., transmitter control signal 332 or LASER_ENABLE 403) to a disable state. Setting the transmitter control signal to a disable state prevents current from passing through a laser (e.g., transmitter 340 or laser diode DLASER) of the lidar device, such that the laser does not emit an optical signal.

At step 508, a controller may set a power control signal (e.g., power control signal 306 or CHARGE_CLASER 418) to an enable state to cause a power supply to charge an energy storage capacitor of the power storage module (e.g., power storage module 302 or power storage module 420). The energy storage capacitor may be the capacitor CLASER described with respect to FIG. 4. The energy storage capacitor may charge to a voltage provided by the power supply VLASER, such that the voltage is the same at nodes 401 and 402. The energy storage capacitor may be coupled to the laser (e.g., laser diode DLASER) of the PCM and may be used to power (e.g., provide a current to) the laser.

At step 510, a controller may set a transmitter power monitor reset signal (e.g., TPM reset control signal 314 or TPM_RESET 410) and a transmitter power monitor sampling signal (e.g., TPM sampling control signal 316 or TPM_SAMPLE 417) to an enable state to discharge one or more energy storage capacitors. The one or more energy storage capacitors may include one or more of the capacitors included in the TPM 430 and the power storage module 420, including the capacitors CTPM_GAIN, CHOLD1, CHOLD2, and CTPM_IN. Discharging the one or more energy storage capacitors for a duration of time ensures that the energy storage capacitors are discharged to baseline voltage levels (e.g., approximately 0 V).

At step 512, the logic module (e.g., logic module 322 or logic module TPM ALGORITHM LOGIC) of the power configuration module (e.g., power configuration module 320 or power configuration module 440) may measure an output of the transmitter power monitor (e.g., TPM 312 or TPM 430) to determine a reference energy dissipation value. The logic module TPM ALGORITHM LOGIC may measure the output of the TPM 420 at the node TPM_DOUT 411. The output may be a digital voltage output as described herein.

At step 514, a controller may set the power control signal (e.g., power control signal 306 or CHARGE_CLASER 418) to a disable state to disable charging the energy storage capacitor of the power storage module (e.g., power storage module 302 or power storage module 420). The energy storage capacitor may be the capacitor CLASER described with respect to FIG. 4. After setting the power control signal to the disable state, the voltage of the capacitor CLASER may be approximately equivalent to the voltage provided by the power supply VLASER, such that the voltage is approximately equivalent at the nodes 401 and 402. In some cases, the voltage stored by the capacitor CLASER can be provided to the laser diode DLASER.

At step 516, a controller may set the transmitter power monitor reset signal (e.g., TPM reset control signal 314 or TPM_RESET 410) to a disable state to enable the one or more energy storages to charge based on (e.g., in response to) an emission of an optical signal (e.g., by the laser diode DLASER). The one or more energy storage capacitors may include one or more of capacitors included in the TPM 430 and the power storage module 420, including the capacitors CTPM_GAIN, CHOLD1, CHOLD2, and CTPM_IN.

At step 518, a controller may set the transmitter control signal (e.g., transmitter control signal 332 or LASER_ENABLE 403) to an enable state to enable current to pass through the laser (e.g., transmitter 340 or laser diode DLASER), thereby causing the laser to emit an optical signal. By setting the transmitter control signal to an enable state, the switch SWITCH_TRANSMITTER may be connected (e.g., closed) and the capacitor CLASER may discharge a voltage (e.g., as stored in step 514). Discharging the capacitor CLASER may cause a current to pass from the capacitor CLASER through the laser diode DLASER as described herein, thereby causing the laser diode DLASER to emit an optical signal. The current may further pass through the variable resistor RTX_ADJUST (e.g., as previously configured by the control voltage in step 502). The resistance of the variable resistor RTX_ADJUST may determine the magnitude of the current that passes through the laser diode DLASER, which corresponds to the power level of the emitted optical signal. Emission of the optical signal may cause the capacitors CTPM_GAIN, CHOLD1, CHOLD2, and CTPM_IN to charge based on (e.g., proportionally to) the voltage discharged by the capacitor CLASER and the energy dissipated by the laser diode DLASER.

At step 520, a controller may set, after a duration of time, the transmitter power monitor sampling signal (e.g., TPM sampling control signal 316 or TPM_SAMPLE 417) to a disable state to cause the one or more energy storage capacitors to cease charging and/or to maintain one or more voltages. The one or more energy storage capacitors may include one or more of the capacitors included in the TPM 430 and the power storage module 420, including at least the capacitors CHOLD1 and CHOLD2. The duration of time may be configured based on the response time (e.g., propagation time) of the operational amplifiers U3 and U2 included in the TPM 430, such that the energy storage capacitors may have a sufficient amount of time to charge in response to the dissipation of the energy through the laser diode DLASER. Any suitable duration of time may be chosen based on the configuration of the operational amplifiers in the TPM 430.

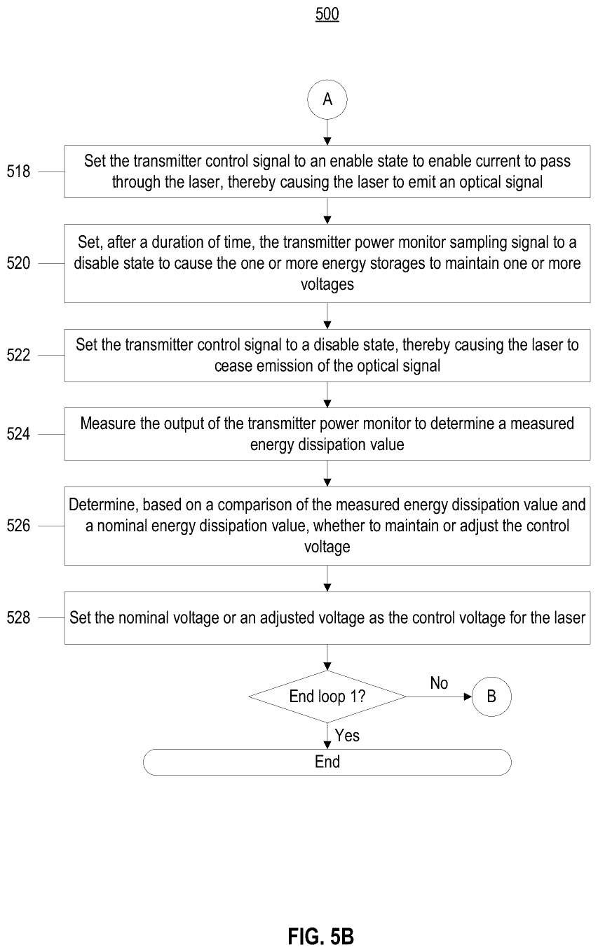

At step 522, a controller may set the transmitter control signal (e.g., transmitter control signal 332 or LASER_ENABLE 403) to a disable state, thereby causing the laser (e.g., transmitter 340 or laser diode DLASER) to cease emission of the optical signal. By disabling the transmitter control signal, current may be impeded from passing through the laser diode DLASER and the variable resistor RTX_ADJUST, such that the laser diode DLASER cannot emit an optical signal. The controller may set the transmitter control signal to a disable state based on a configured optical pulse width for the optical signal. As an example, the controller may set the transmitter control signal to a disable state 2 μs after the controller set the transmitter control signal to an enable state, such that the pulse width (also referred to as “duration”) of the optical signal is 2 μs. An example of timing for the control signals of the PCM during the emission of an optical signal is described below with respect to FIG. 6.

At step 524, the logic module (e.g., logic module 322 or logic module TPM ALGORITHM LOGIC) of the power configuration module (e.g., power configuration module 320 or power configuration module 440) may measure the output of the transmitter power monitor (e.g., TPM 312 or TPM 430) to determine an energy dissipation value corresponding to the emitted optical signal. The logic module may measure and/or otherwise sample the digital voltage output provided at the node TPM_DOUT 411. In some cases, the logic module may determine a difference between the measured energy dissipation value for the emitted optical signal and the reference energy dissipation value (e.g., as determined at step 512).

At step 526, the logic module (e.g., logic module 322 or logic module TPM ALGORITHM LOGIC) may determine, based on a comparison of the measured energy dissipation value and a nominal energy dissipation value (e.g., for the nominal voltage corresponding to the operating mode), whether to maintain or adjust an operating parameter (e.g., bias code) corresponding to the control voltage. In some cases, the logic module may determine a differential value between the measured energy dissipation value and a reference energy dissipation value (e.g., as determined at step 512) and may determine whether to maintain or adjust the control voltage based on a comparison of the differential value and the nominal energy dissipation value. In some cases, the nominal energy dissipation value is a differential between a measured energy dissipation value and a reference energy dissipation value obtained under nominal operating conditions as described herein.

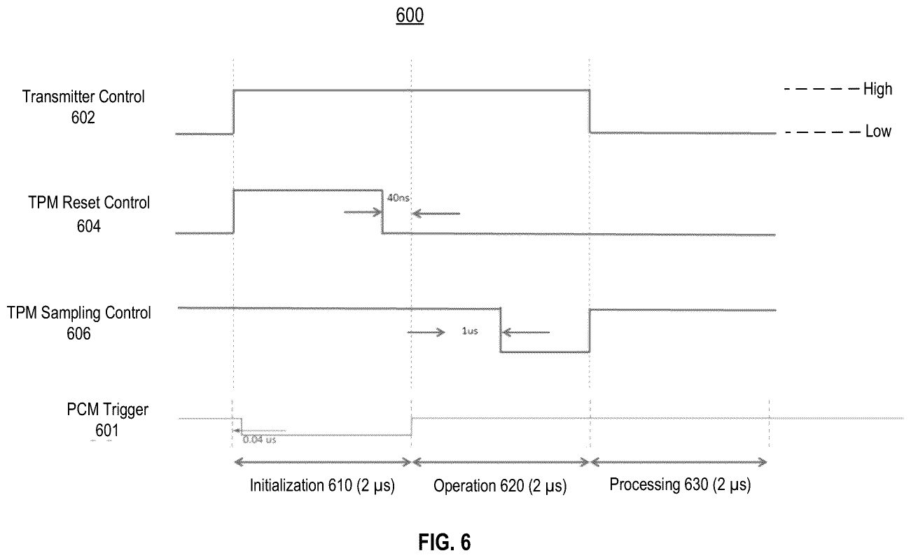

The logic module may decide to maintain the operating parameter (e.g., bias code) corresponding to the present control voltage (e.g., nominal voltage or adjusted control voltage based on the control voltage set in step 502) if the measured energy dissipation value (or the differential value) is within a range corresponding to the nominal energy dissipation value. As an example, the logic module may decide to maintain the operating parameter corresponding to the present control voltage if a differential between the measured energy dissipation value and the nominal energy dissipation value is within a configured threshold (e.g., +/−10% of the nominal energy dissipation value). The logic module may decide to adjust the operating parameter corresponding to a present control voltage if the energy dissipation value (or the differential value) is external to a range corresponding to the nominal energy dissipation value. In some cases, the logic module may access and/or otherwise include one or more operating parameters (e.g., bias codes) each corresponding to respective control voltages that may be applied to the laser. As an example, the logic module may include a lookup table corresponding to operating parameters (e.g., each corresponding to a respective control voltage) and corresponding energy dissipation differential values used to select from the operating parameters. The logic module may further determine whether to maintain or adjust the operating parameter corresponding to a control voltage for the operating mode as described below with respect to FIG. 7.

At step 528, the logic module may set the nominal voltage or an adjusted voltage as the control voltage for the operating mode of the channel. To set the nominal voltage or an adjusted voltage as the control voltage for the operating mode of the laser, the logic module may maintain or adjust an operating parameter corresponding to the control voltage for the operating mode of the laser. The logic module may set the control voltage such that the laser may emit one or more optical signals having energy dissipation values corresponding to the nominal energy dissipation value for the operating mode. In some cases, based on setting an adjusted voltage as the control voltage, the method may revert to step 508 to determine whether the adjusted voltage results in a measured energy dissipation value corresponding to the nominal energy dissipation value. In some cases, based on setting (e.g., maintaining) the nominal voltage as the control voltage for the operating mode, the method may revert to step 508 to confirm whether the nominal voltage results in a measured energy dissipation value corresponding to the nominal energy dissipation value. In some cases, if the control voltage for the operating mode of the channel was previously adjusted from the nominal voltage (e.g., as described for step 502), the logic module may set the previously adjusted voltage or a newly adjusted voltage as the control voltage for the operating mode of the channel.

In some embodiments, the method 500 may be executed for any suitable number of optical signals. The method 500 may be executed (e.g., repeated) irrespective of whether the measured energy dissipation value corresponds to the nominal energy dissipation value. Any suitable number of consecutive or non-consecutive samples of the measured energy dissipation value may be required to be within a range corresponding to the nominal energy dissipation value before the method 500 can conclude. For example, a controller may require that the measured energy dissipation values corresponding to three consecutive emitted optical signals are within a +/−10% range of the nominal energy dissipation value before the method 500 may conclude. In some cases, the method 500 may be executed after the control voltage for an operating mode has been adjusted from the nominal voltage of the operating mode, such that the method 500 determines whether to maintain the control voltage or further adjust the control voltage. As an example, an adjusted control voltage may replace the nominal voltage as described for the method 500 in steps 502 and 528.

FIG. 6 shows an example timing diagram 600 for controlling a PCM (e.g., PCM 300 or PCM 400). The control signals shown in FIG. 6 include a PCM trigger signal 601, a transmitter control signal 602, a TPM reset control signal 604, and a TPM sampling control signal 606. The transmitter control signal 602 may correspond to the transmitter control signal 332 and/or to the external connection LASER_ENABLE 403. The TPM reset control signal 604 may correspond to the TPM reset control signal 314 and/or to the external connection TPM_RESET 410. The TPM sampling control signal 606 may correspond to the TPM sampling control signal 316 and/or to the external connection TPM_SAMPLE 417. The timing diagram 600 shows the control signals at logical high (e.g., enabled) and logical low (e.g., disabled) configurations.

In some embodiments, the transmitter control signal 602 is required to be enabled for a laser (e.g., transmitter 340 or laser diode DLASER) to emit an optical signal. If transmitter control signal 602 is enabled, the laser may emit an optical signal when the PCM trigger signal 601 changes from a logical low to a logical high (e.g., at the rising edge of the PCM trigger signal 601). The TPM reset control signal 604 may be enabled and then disabled as shown in FIG. 6 prior to the emission of the optical signal to discharge the one or more energy storage capacitors of the TPM (e.g., TPM 312 or 430). The TPM reset control signal 604 may be required to be disabled (e.g., set to low) for a suitable duration before the emission of the optical signal (e.g., as indicated when the transmitter control signal 602 is enabled and the PCM trigger signal 601 has a rising edge) to allow for the measurement of energy dissipation through the laser. The TPM sampling control signal 606 may be initially enabled as shown in FIG. 6 to allow the one or more energy storage capacitors of the TPM to discharge prior to the emission of the optical signal. The energy dissipated by an energy storage capacitor (e.g., capacitor CLASER) of the lidar device may be measured from the falling edge of the TPM reset control signal 604 to the falling edge of the TPM sampling control signal 606 as shown in FIG. 6. Accordingly, the energy dissipated by the energy storage capacitor may be measured for a duration of 1.04 μs, where the optical signal is emitted for 2 μs as shown in FIG. 6.

As shown in FIG. 6, the timing diagram 600 includes several time periods: an initialization and calibration period 610, an operation period 620, and a processing period 630. As an example, each of the time periods may be 2 μs. The time periods may be of any suitable duration based on the configuration of the PCM and the operation the lidar device. During the initialization period 610, the TPM reset control signal 604 and the TPM sampling control signal 606 may be enabled to cause one or more energy storage capacitors of the TPM to discharge prior to the emission of the optical signal. Before the end of the initialization period 610, the transmitter control signal 602 may be enabled to allow for the emission of an optical signal during the subsequent operation period 620 and the TPM reset control signal 604 may be disabled to allow for the energy storage capacitors to measure the energy dissipation through the laser during the optical signal emission. The PCM trigger signal 601 may be enabled to start the operation period 620, causing the energy storage capacitor corresponding to the laser to discharge and resulting in an emission of an optical signal by the laser. The TPM sampling control signal 606 may remain enabled for a duration corresponding to the time for the energy storage capacitors to charge in response to the emission of the optical signal. The energy storage capacitors may measure an indication of the power level of the emitted optical signal based on charging in response to the emission of the optical signal. As an example, the TPM sampling control signal 606 may remain enabled for 1 μs of the operation period 620. The operation period 620 may end based on the transmitter control signal 602 being disabled. The TPM sampling control signal 606 may be enabled when the transmitter control signal 602 is disabled. During the processing period 630, each control signal may remain enabled or disabled as shown in FIG. 6 and a logic module (e.g., logic module 322 or logic module TPM ALGORITHM LOGIC) may measure a digital voltage output corresponding to the energy dissipation through the laser as described herein.

In some embodiments, based on measuring the output of the TPM (e.g., TPM 312 or 430) to determine an energy dissipation value for the emitted optical signal, the logic module (e.g., logic module 322 or logic module TPM ALGORITHM LOGIC) determines whether to maintain or adjust the control voltage applied to a laser of the lidar device (e.g., by adjusting an operating parameter). In some cases, if the logic module decides to adjust the control voltage, the logic module determines a magnitude of an increase or a decrease to the control voltage. FIG. 7 shows a flowchart of a method 700 for controlling optical power at a lidar device via a PCM (e.g., PCM 300 or 400). The method 700 may be suitable for determining a control voltage for controlling a power level of a future optical signal emission based on measuring a power level (e.g., via an energy dissipation value) of an emitted optical signal. The method 700 may be performed individually for each channel of a lidar device that includes a PCM. As an example, the method 700 may be performed to determine whether to maintain or adjust a control voltage (e.g., as a part of step 526 of the method 500). The method 700 may be executed by components of the PCM (e.g., PCM 300 and/or 400), a control module (e.g., control and data acquisition module 108), a data analysis module (e.g., data analysis and interpretation module 109), and/or any other suitable controller of the lidar device. For example, the control and data acquisition module 108 may process a measured energy dissipation value for comparison to a nominal energy dissipation value to determine whether to modify or maintain a control voltage of a laser. In some cases, the method 700 may be configured to execute for each operating mode of a channel of the lidar device. The method 700 may be executed for any suitable number of optical signals emitted by a channel's transmitter (e.g., laser).

At step 702, a logic module (e.g., logic module 322 or logic module TPM ALGORITHM LOGIC) may determine whether a differential between a measured energy dissipation value (e.g., as measured at step 524 in the method 500) and a nominal energy dissipation value is greater than or equal to a threshold value. The logic module may make the determination based on measuring the output of the TPM (e.g., TPM 312 or 430) to determine the energy dissipation value for an emitted optical signal. As described herein, the nominal energy dissipation value may correspond to a nominal voltage applied to a channel's transmitter to cause emission of an optical signal, where the nominal voltage was used as a control voltage for the channel's transmitter under nominal operation conditions (e.g., during a calibration method). Any suitable threshold value may be chosen based on the desired sensitivity of the method 700. As an example, the threshold value may be chosen to be 10% of the nominal energy dissipation value, such that the logic module determines whether the measured energy dissipation value is within a range defined between 90% of the nominal energy dissipation value and 110% of the nominal energy dissipation value. If the differential between the measured energy dissipation value and the nominal energy dissipation value is greater than or equal to the threshold value, the method 700 proceeds to step 704. If the differential between the measured energy dissipation value and the nominal energy dissipation value is less than the threshold value, the method 700 proceeds to step 706. As an example, the step 702 may execute after step 524 of the method 500 as a part of step 526.

After determining that the differential between the measured energy dissipation value and the nominal energy dissipation value is greater than or equal to the threshold value, the logic module may determine which of the measured energy dissipation value and the nominal energy dissipation value is larger in order to determine whether to increase or decrease the control voltage. Accordingly, at step 704, the logic module (e.g., logic module 322 or logic module TPM ALGORITHM LOGIC) may determine whether the measured energy dissipation value is greater than the nominal energy dissipation value. If the measured energy dissipation value is greater than the nominal energy dissipation value, the method 700 proceeds to step 708. If the measured energy dissipation value is less than the nominal energy dissipation value, the method 700 proceeds to step 710.

At step 706, the logic module (e.g., logic module 322 or logic module TPM ALGORITHM LOGIC) may decide to maintain the present control voltage for the laser (e.g., transmitter 340 or laser diode DLASER). In some cases, the logic module decides to maintain the present control voltage if the differential between the measured energy dissipation value and the nominal energy dissipation value is less than the threshold value. In other cases, the logic module decides to maintain the present control voltage if the logic module decided to increase the control voltage when the present control voltage is already configured to a maximum control voltage or if the logic module decided to decrease the control voltage when the present control voltage is already configured to a minimum control voltage. The present control voltage may be the nominal voltage (e.g., as described with respect to step 502 of the method 500) or a previously adjusted control voltage (e.g., determined from the method 500).

At step 708, the logic module determines whether the present control voltage is equivalent to a minimum control voltage for the laser (e.g., transmitter 340 or laser diode DLASER). The laser may be configured to have a minimum control voltage based on the operating parameter used to control the control voltage, such that the control voltage of the laser may not be less than the minimum control voltage. Any suitable minimum control voltage may be defined for the laser based on the application of the lidar device. If the present control voltage is equivalent to the minimum control voltage, the method 700 proceeds to step 706. If the present control voltage is not equivalent to the minimum control voltage, the method 700 proceeds to step 712.

At step 710, the logic module determines whether the present control voltage is equivalent to a maximum control voltage for the laser (e.g., transmitter 340 or laser diode DLASER). The laser may be configured to have a maximum control voltage based on the operating parameter used to control the control voltage, such that the control voltage of the laser may not be greater than the maximum control voltage. Any suitable maximum control voltage may be defined for the laser based on the application of the lidar device. If the present control voltage is equivalent to the maximum control voltage, the method 700 proceeds to step 706. If the present control voltage is not equivalent to the maximum control voltage, the method 700 proceeds to step 714.

At step 712, the logic module decides to decrease the present control voltage. In some cases, the logic module decides to decrease the present control voltage by a configured step size. The logic module may decide to decrease the present control voltage based on its determination that the present control voltage is not equivalent to the minimum control voltage. The step size may correspond to a fixed voltage value or a variable voltage value based on a differential of control voltages corresponding to consecutive operating parameters (e.g., bias codes). In some cases, the step size may correspond to a change in an operating parameter (e.g., bias code), where a change in an operating parameter corresponds to a respective change in the control voltage. The logic module may decide to decrease the present control voltage by one or more operating parameters. As an example, after deciding to decrease the present control voltage, the logic module may adjust an operating parameter to a next available operating parameter corresponding to a reduced control voltage. After deciding to decrease the present control voltage, the logic module may determine an adjusted voltage. The adjusted voltage may be configured (e.g., set) as the control voltage (e.g., as described in step 528 of the method 500) corresponding to the operating mode.

At step 714, the logic module decides to increase the present control voltage. In some cases, the logic module decides to increase the present control voltage by a configured step size. The logic module may decide to increase the present control voltage based on its determination that the present control voltage is not equivalent to the maximum control voltage. The step size may correspond to a fixed voltage value or a variable voltage value based on a differential of control voltages corresponding to consecutive operating parameters (e.g., bias codes). In some cases, the step size may correspond to a change in an operating parameter (e.g., bias code), where a change in an operating parameter corresponds to a respective change in the control voltage. The logic module may decide to increase the present control voltage by one or more operating parameters. As an example, after deciding to increase the present control voltage, the logic module may adjust an operating parameter to a next available operating parameter corresponding to an increased control voltage. After deciding to increase the present control voltage, the logic module may determine an adjusted voltage. The adjusted voltage may be configured (e.g., set) as the control voltage (e.g., as described in step 528 of the method 500) corresponding to the operating mode.

Each operating parameter of a plurality of operating parameters may correspond to a respective control voltage. A differential between control voltages of consecutive operating parameters may be fixed or variable. As an example, if the differential between control voltages of consecutive operating parameters is variable, the control voltages may vary logarithmically or exponentially.

### Some Examples of Continuous Wave (CW) Lidar Systems

As discussed above, some lidar systems may use a continuous wave (CW) laser to detect the range and/or velocity of targets, rather than pulsed TOF techniques. Such systems include continuous wave (CW) coherent lidar systems and frequency modulated continuous wave (FMCW) coherent lidar systems. For example, any of the lidar systems 100, 202, 250, and 270 described above can be configured to operate as a CW coherent lidar system or an FMCW coherent lidar system.

Lidar systems configured to operate as CW or FMCW systems can avoid the eye safety hazards commonly associated with pulsed lidar systems (e.g., hazards that arise from transmitting optical signals with high peak power). In addition, coherent detection may be more sensitive than direct detection and can offer better performance, including single-pulse velocity measurement and immunity to interference from solar glare and other light sources, including other lidar systems and devices.

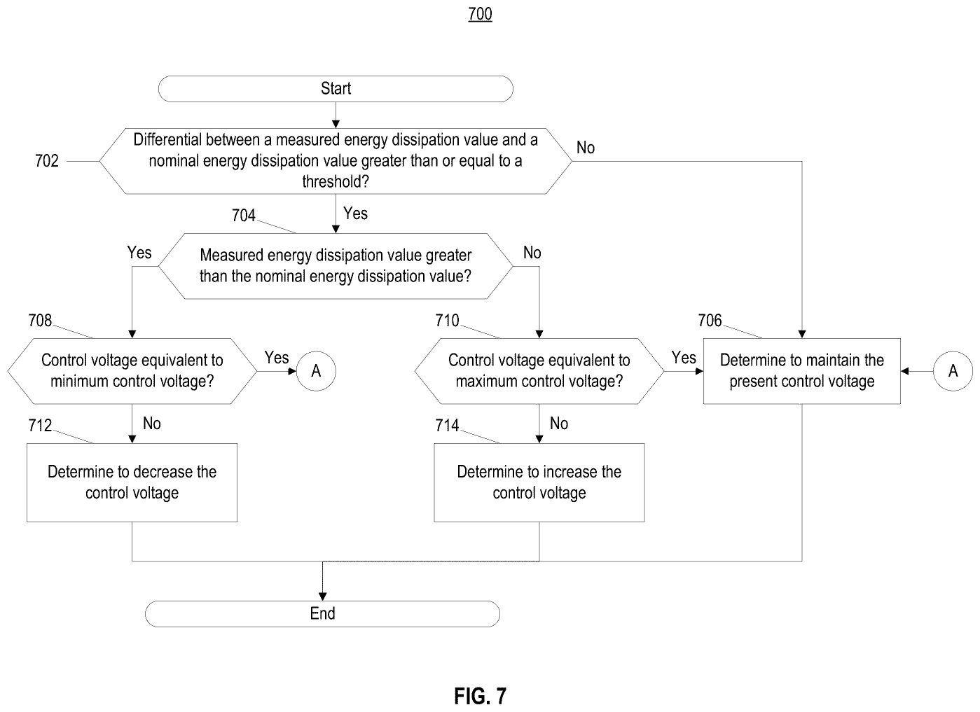

FIG. 8 illustrates an exemplary CW coherent lidar system 800 configured to determine the radial velocity (or speed) of a target. Lidar system 800 includes a laser 802 configured to produce a laser signal which is provided to a splitter 804. The laser 802 may provide a laser signal having a substantially constant laser frequency.

In one example, the splitter 804 provides a first split laser signal Tx1 to a direction selective device 806, which provides (e.g., forwards) the signal Tx1 to a scanner 808. In some examples, the direction selective device 806 is a circulator. The scanner 808 uses the first laser signal Tx1 to transmit light emitted by the laser 802 and receives light reflected by the target 810 (e.g., “reflected light” or “reflections”). The reflected light signal Rx is provided (e.g., passed back) to the direction selective device 806. The second laser signal Tx2 (provided by the splitter 804) and the reflected light signal Rx are provided to a coupler (also referred to as a mixer) 812. The mixer may use the second laser signal Tx2 as a local oscillator (LO) signal and mix it with the reflected light signal Rx. The mixer 812 may be configured to mix the reflected light signal Rx with the local oscillator signal LO. The mixer 812 may provide the mixed optical signal to differential photodetector 814, which may generate an electrical signal representing the beat frequency f_{beat} of the mixed optical signals, where f_{beat}=|f_{Tx2}−f_{Rx}| (the absolute value of the difference between the frequencies of the mixed optical signals). In some embodiments, the current produced by the differential photodetector 814 based on the mixed light may have the same frequency as the beat frequency f_{beat}. The current may be converted to a voltage by an amplifier (e.g., a transimpedance amplifier (TIA)), which may be provided (e.g., fed) to an analog-to-digital converter (ADC) 816 configured to convert the analog voltage signal to digital samples for a target detection module 818. The target detection module 818 may be configured to determine (e.g., calculate) the radial velocity of the target 810 based on the digital sampled signal with the beat frequency f_{beat}.

In one example, the target detection module 818 may identify Doppler frequency shifts using the beat frequency f_{beat} and determine the radial velocity of the target 810 based on those shifts. For example, the radial velocity of the target 810 can be calculated using the following relationship:

$${f}_{d} = \frac{2}{λ} {v}_{t}$$

where, f_{d} is the Doppler frequency shift, λ is the wavelength of the laser signal, and vₜ is the radial velocity of the target 810. In some examples, the direction of the target 810 is indicated by the sign of the Doppler frequency shift f_{d}. For example, a positive signed Doppler frequency shift may indicate that the target 810 is traveling towards the system 800 and a negative signed Doppler frequency shift may indicate that the target 810 is traveling away from the system 800.

In one example, a Fourier Transform calculation is performed using the digital samples from the ADC 816 to recover the desired frequency content (e.g., the Doppler frequency shift) from the digital sampled signal. For example, a controller (e.g., target detection module 818) may be configured to perform a Discrete Fourier Transform (DFT) on the digital samples. In certain examples, a Fast Fourier Transform (FFT) can be used to calculate the DFT on the digital samples. In some examples, the Fourier Transform calculation (e.g., DFT) can be performed iteratively on different groups of digital samples to generate a target point cloud.

While the lidar system 800 is described above as being configured to determine the radial velocity of a target, it should be appreciated that the system can be configured to determine the range and/or radial velocity of a target. For example, the lidar system 800 can be modified to use laser chirps to detect the velocity and/or range of a target.

Some examples have been described in which a DFT is used to generate points of a point cloud based on a group of samples. However, frequency analysis techniques (e.g., spectrum analysis techniques) other than the DFT may be used to generate points of a point cloud based on a group of samples. Any suitable frequency analysis technique may be used, including, without limitation, Discrete Cosine transform (DCT), Wavelet transform, Auto-Regressive moving average (ARMA), etc.

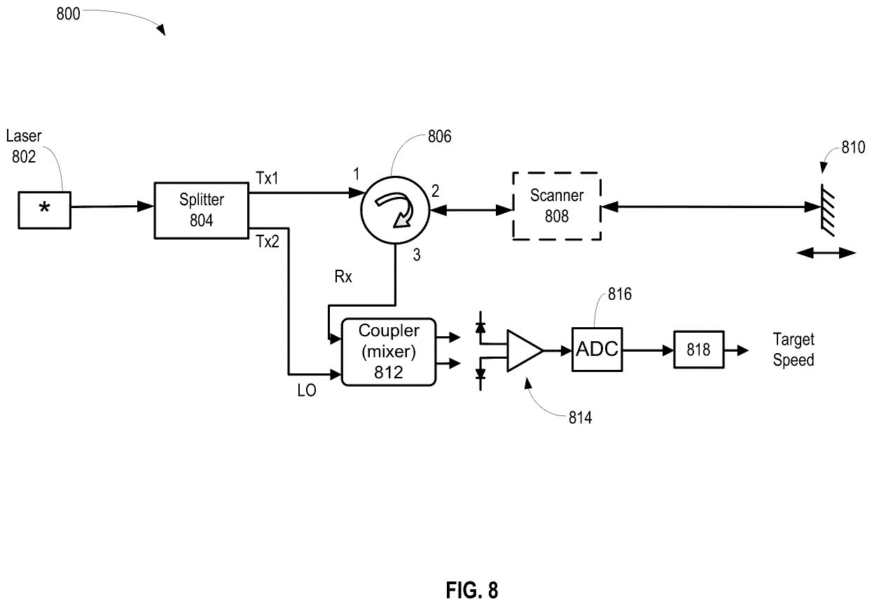

FIG. 9 illustrates an exemplary FMCW coherent lidar system 900 configured to determine the range and/or radial velocity of a target. Lidar system 900 includes a laser 902 configured to produce a laser signal which is fed into a splitter 904. The laser is “chirped” (e.g., the center frequency of the emitted laser beam is increased (“ramped up” or “chirped up”) or decreased (“ramped down” or “chirped down”) over time (or, equivalently, the central wavelength of the emitted laser beam changes with time within a waveband). In various embodiments, the laser frequency is chirped quickly such that multiple phase angles are attained. In one example, the frequency of the laser signal is modulated by changing the laser operating parameters (e.g., current/voltage) or using a modulator included in the laser source 902; however, in other examples, an external modulator can be placed between the laser source 902 and the splitter 904.

In other examples, the laser frequency can be “chirped” by modulating the phase of the laser signal (or light) produced by the laser 902. In one example, the phase of the laser signal is modulated using an external modulator placed between the laser source 902 and the splitter 904; however, in some examples, the laser source 902 may be modulated directly by changing operating parameters (e.g., current/voltage) or may include an internal modulator. Similar to frequency chirping, the phase of the laser signal can be increased (“ramped up”) or decreased (“ramped down”) over time.

Some examples of systems with FMCW-based lidar sensors have been described. However, some embodiments of the techniques described herein may be implemented using any suitable type of lidar sensors including, without limitation, any suitable type of coherent lidar sensors (e.g., phase-modulated coherent lidar sensors). With phase-modulated coherent lidar sensors, rather than chirping the frequency of the light produced by the laser (as described above with reference to FMCW techniques), the lidar system may use a phase modulator placed between the laser 902 and the splitter 904 to generate a discrete phase modulated signal, which may be used to measure range and radial velocity.

As shown, the splitter 904 provides a first split laser signal Tx1 to a direction selective device 906, which provides (e.g., forwards) the signal Tx1 to a scanner 908. The scanner 908 uses the first laser signal Tx1 to transmit light emitted by the laser 902 and receives light reflected by the target 910. The reflected light signal Rx is provided (e.g., passed back) to the direction selective device 906. The second laser signal Tx2 and reflected light signal Rx are provided to a coupler (also referred to as a mixer) 912. The mixer may use the second laser signal Tx2 as a local oscillator (LO) signal and mix it with the reflected light signal Rx. The mixer 912 may be configured to mix the reflected light signal Rx with the local oscillator signal LO to generate a beat frequency f_{beat}. The mixed signal with beat frequency f_{beat} may be provided to a differential photodetector 914 configured to produce a current based on the received light. The current may be converted to voltage by an amplifier (e.g., a transimpedance amplifier (TIA)), which may be provided (e.g., fed) to an analog-to-digital converter (ADC) 916 configured to convert the analog voltage to digital samples for a target detection module 918. The target detection module 918 may be configured to determine (e.g., calculate) the range and/or radial velocity of the target 910 based on the digital sample signal with beat frequency f_{beat}.

Laser chirping may be beneficial for range (distance) measurements of the target. In comparison, Doppler frequency measurements are generally used to measure target velocity. Resolution of distance can depend on the bandwidth size of the chirp frequency band such that greater bandwidth corresponds to finer resolution, according to the following relationships:

$$Range resolution : Δ R = \frac{c}{2 BW} ( given a perfectly linear chirp ) , and$$

$$Range : R = \frac{{f}_{beat} c {T}_{ChirpRamp}}{2 BW}$$

where c is the speed of light, BW is the bandwidth of the chirped laser signal, f_{beat} is the beat frequency, and T_{ChirpRamp} is the time period during which the frequency of the chirped laser ramps up (e.g., the time period corresponding to the up-ramp portion of the chirped laser). For example, for a distance resolution of 3.0 cm, a frequency bandwidth of 5.0 GHz may be used. A linear chirp can be an effective way to measure range and range accuracy can depend on the chirp linearity. In some instances, when chirping is used to measure target range, there may be range and velocity ambiguity. In particular, the reflected signal for measuring velocity (e.g., via Doppler) may affect the measurement of range. Therefore, some exemplary FMCW coherent lidar systems may rely on two measurements having different slopes (e.g., negative and positive slopes) to remove this ambiguity. The two measurements having different slopes may also be used to determine range and velocity measurements simultaneously.

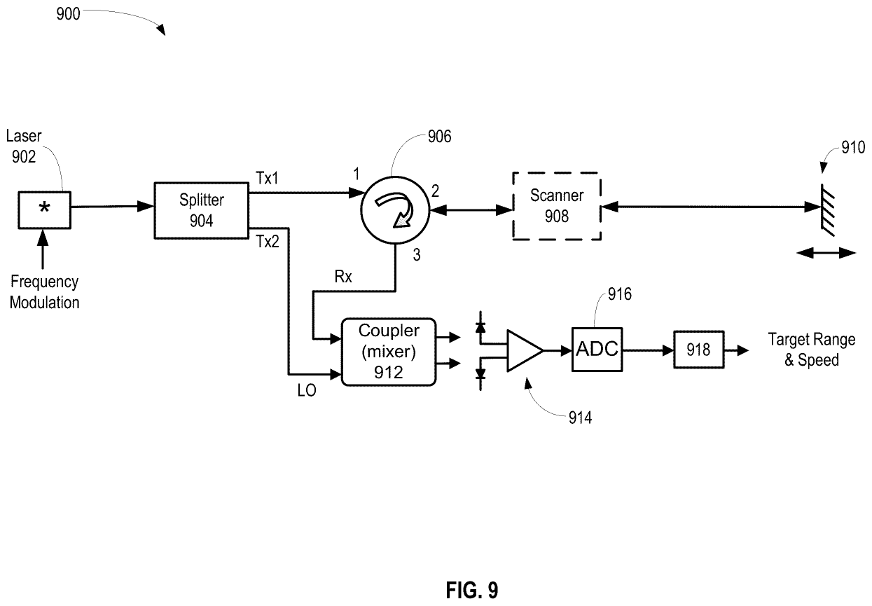

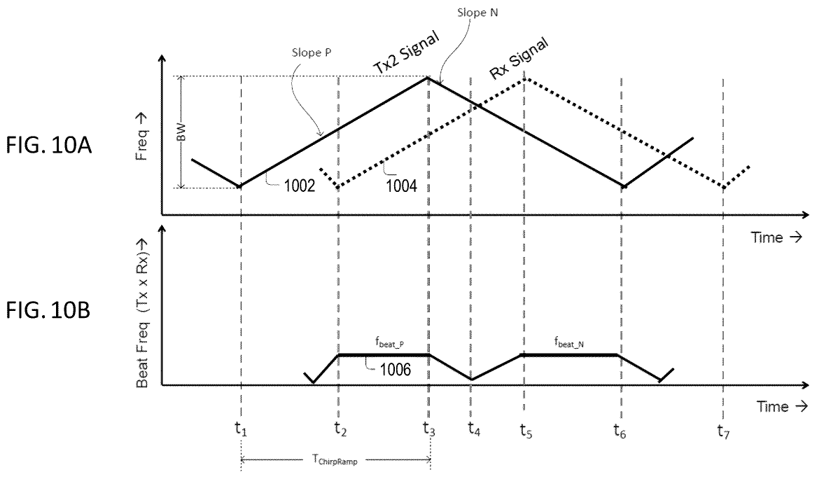

FIG. 10A is a plot of ideal (or desired) frequency chirp as a function of time in the transmitted laser signal Tx (e.g., signal Tx2), depicted in solid line 1002, and reflected light signal Rx, depicted in dotted line 1004. As depicted, the ideal Tx signal has a positive linear slope between time t1 and time t3 and a negative linear slope between time t3 and time t6. Accordingly, the ideal reflected light signal Rx returned with a time delay td of approximately t2−t1 has a positive linear slope between time t2 and time t5 and a negative linear slope between time t5 and time t7.

FIG. 10B is a plot illustrating the corresponding ideal beat frequency f_{beat} 1006 of the mixed signal Tx2×Rx. Note that the beat frequency f_{beat} 1006 has a constant value between time t2 and time t3 (corresponding to the overlapping up-slopes of signals Tx2 and Rx) and between time t5 and time t6 (corresponding to the overlapping down-slopes of signals Tx2 and Rx).

The positive slope (“Slope P”) and the negative slope (“Slope N”) (also referred to as positive ramp (or up-ramp) and negative ramp (or down-ramp), respectively) can be used to determine range and/or velocity. In some instances, referring to FIGS. 10A-10B, when the positive and negative ramp pair is used to measure range and velocity simultaneously, the following relationships are utilized:

$$Range : R = \frac{{cT}_{ChirpRamp} \frac{( {f}_{beat \_ P} + {f}_{beat \_ N} )}{2}}{2 BW} , and$$

$$Velocity : V = \frac{λ \frac{( {f}_{beat \_ P} + {f}_{beat \_ N} )}{2}}{2}$$

where f_{beat_P} and f_{beat_N} are beat frequencies generated during positive (P) and negative (N) slopes of the chirp 1002 respectively and λ is the wavelength of the laser signal.

In one example, the scanner 908 of the lidar system 900 is used to scan the environment and generate a target point cloud from the acquired scan data. In some examples, the lidar system 900 can use processing methods that include performing one or more Fourier Transform calculations, such as a Fast Fourier Transform (FFT) or a Discrete Fourier Transform (DFT), to generate the target point cloud from the acquired scan data. Being that the system 900 is capable of measuring range, each point in the point cloud may have a three-dimensional location (e.g., x, y, and z) in addition to radial velocity. In some examples, the x-y location of each target point corresponds to a radial position of the target point relative to the scanner 908. Likewise, the z location of each target point corresponds to the distance between the target point and the scanner 908 (e.g., the range). In one example, each target point corresponds to one frequency chirp 1002 in the laser signal. For example, the samples collected by the system 900 during the chirp 1002 (e.g., t1 to t6) can be processed to generate one point in the point cloud.

### Additional Embodiments, Computing Devices, and Information Handling Systems

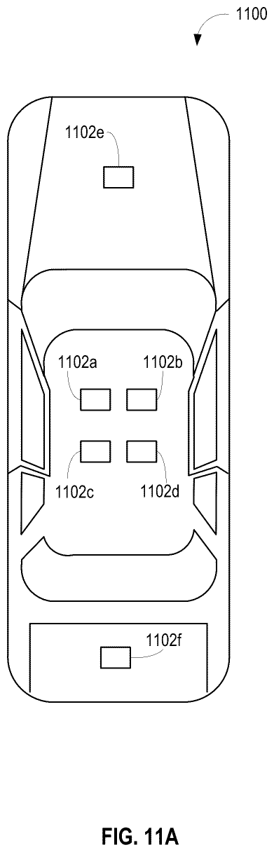

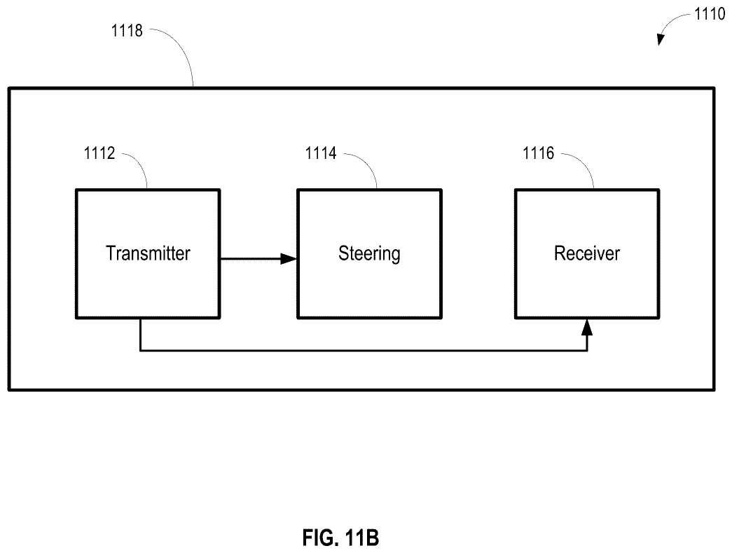

In some embodiments, lidar systems and techniques described herein may be used to provide mapping and/or autonomous navigation for a vehicle. FIG. 11A illustrates a vehicle 1100 having a plurality of sensors 1102. As shown, a first sensor 1102a, a second sensor 1102b, a third sensor 1102c, and a fourth sensor 1102d may be positioned in a first location on (or inside) the vehicle 1100 (e.g., the roof). Likewise, a fifth sensor 1102e may be positioned in a second location on (or inside) the vehicle 1100 (e.g., the front of the vehicle 1100) and a sixth sensor 1102f may be positioned in a third location on (or inside) the vehicle 1100 (e.g., the back of the vehicle 1100). In other examples, a different number or configuration of sensors may be used.

In some examples, at least one sensor of the plurality of sensors 1102 is configured to provide (or enable) 3D mapping of the vehicle's surroundings. In certain examples, at least one sensor of the plurality of sensors 1102 is used to provide autonomous navigation for the vehicle 1100 within an environment. In one example, each sensor 1102 includes at least one lidar system, device, or chip. The lidar system(s) included in each sensor 1102 may include any of the lidar systems disclosed herein. In some examples, at least one sensor of the plurality of sensors 1102 may be a different type of sensor (e.g., camera, radar, etc.). In one example, the vehicle 1100 is a car; however, in other examples, the vehicle 1100 may be a truck, boat, plane, drone, vacuum cleaner (e.g., robot vacuum cleaner), robot, train, tractor, ATV, or any other type of vehicle or moveable object.

In some embodiments, lidar systems and techniques described herein may be implemented using Silicon photonics (SiP) technologies. SiP is a material platform from which photonic integrated circuits (PICs) can be produced. SiP is compatible with CMOS (electronic) fabrication techniques, which allows PICs to be manufactured using established foundry infrastructure. In PICs, light propagates through a patterned silicon optical medium that lies on top of an insulating material layer (e.g., silicon on insulator (SOI)). In some cases, direct bandgap materials (e.g., indium phosphide (InP)) are used to create light (e.g., laser) sources that are integrated in an SiP chip (or wafer) to drive optical or photonic components within a photonic circuit. SiP technologies are increasingly used in optical datacom, sensing, biomedical, automotive, astronomy, aerospace, augmented reality (AR) applications, virtual reality (VR) applications, artificial intelligence (AI) applications, navigation, image identification, drones, robotics, etc.

FIG. 11B is a block diagram of a silicon photonic integrated circuit (PIC) 1110 in accordance with aspects described herein. In one example, the lidar systems described herein can be implemented as the PIC 1110. The PIC 1110 includes a transmitter module 1112, a steering module 1114, and a receiver module 1116. As shown, the transmitter module 1112, the steering module 1114, and the receiver module 1116 are integrated on a silicon substrate 1118. In other examples, the transmitter module 1112, the steering module 1114, or the receiver module 1116 may be included on a separate substrate. In some embodiments, the steering module 1114 is used by the PIC 1110 in connection with transmission (e.g., emission) and reception (e.g., collection) of optical signals. In some examples, the silicon substrate 1118 is an SOI substrate with a silicon layer (e.g., between 200 nm and 10 micron thick) disposed over an oxide layer (e.g., approximately 2 micron thick). In certain examples, the silicon substrate 1118 can include multiple silicon and/or oxide layers.

In one example, the transmitter module 1112 includes at least one laser source. In some examples, the laser source(s) are implemented using a direct bandgap material (e.g., InP) and integrated on the silicon substrate 1118 via hybrid integration. The transmitter module 1112 may also include at least one splitter, a combiner, and/or a direction selective device that are implemented on the silicon substrate 1118 via monolithic or hybrid integration. In some examples, the laser source(s) are external to the PIC 1110 and the laser signal(s) can be provided to the transmission module 1112.

In some embodiments, lidar systems and techniques described herein may be implemented using micro-electromechanical system (MEMS) devices. A MEMS device is a miniature device that has both mechanical and electronic components. The physical dimension of a MEMS device can range from several millimeters to less than one micrometer. Lidar systems may include one or more scanning mirrors implemented as a MEMS mirror (or an array of MEMS mirrors). Each MEMS mirror may be a single-axis MEMS mirror or dual-axis MEMS mirror. The MEMS mirror(s) may be electromagnetic mirrors. A control signal is provided to adjust the position of the mirror to direct light in at least one scan direction (e.g., horizontal and/or vertical). The MEMS mirror(s) can be positioned to steer light transmitted by the lidar system and/or to steer light received by the lidar system. MEMS mirrors are compact and may allow for smaller form-factor lidar systems, faster control speeds, and more precise light steering compared to other mechanical-scanning lidar methods. MEMS mirrors may be used in solid-state (e.g., stationary) lidar systems and rotating lidar systems.

In embodiments, aspects of the techniques described herein (e.g., timing the emission of the transmitted signal, processing received return signals, and so forth) may be directed to or implemented on information handling systems/computing systems. For purposes of this disclosure, a computing system may include any instrumentality or aggregate of instrumentalities operable to compute, calculate, determine, classify, process, transmit, receive, retrieve, originate, route, switch, store, display, communicate, manifest, detect, record, reproduce, handle, or utilize any form of information, intelligence, or data for business, scientific, control, or other purposes. For example, a computing system may be a personal computer (e.g., laptop), tablet computer, phablet, personal digital assistant (PDA), smart phone, smart watch, smart package, server (e.g., blade server or rack server), network storage device, or any other suitable device and may vary in size, shape, performance, functionality, and price.

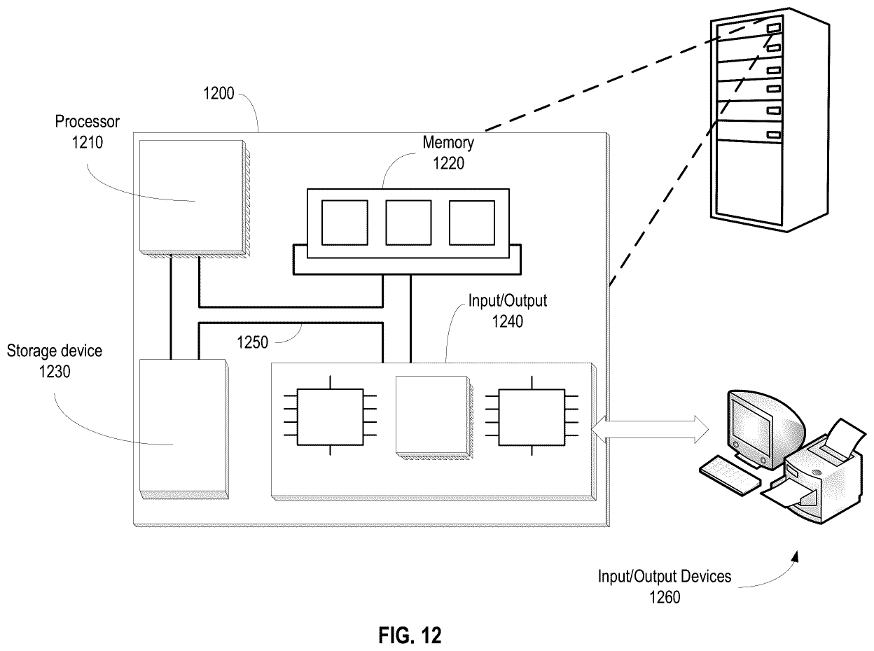

FIG. 12 is a block diagram of an example computer system 1200 that may be used in implementing the technology described in this document. General-purpose computers, network appliances, mobile devices, or other electronic systems may also include at least portions of the system 1200. The system 1200 includes a processor 1210, a memory 1220, a storage device 1230, and an input/output device 1240. Each of the components 1210, 1220, 1230, and 1240 may be interconnected, for example, using a system bus 1250. The processor 1210 is capable of processing instructions for execution within the system 1200. In some implementations, the processor 1210 is a single-threaded processor. In some implementations, the processor 1210 is a multi-threaded processor. In some implementations, the processor 1210 is a programmable (or reprogrammable) general purpose microprocessor or microcontroller. The processor 1210 is capable of processing instructions stored in the memory 1220 or on the storage device 1230.

The memory 1220 stores information within the system 1200. In some implementations, the memory 1220 is a non-transitory computer-readable medium. In some implementations, the memory 1220 is a volatile memory unit. In some implementations, the memory 1220 is a non-volatile memory unit.

The storage device 1230 is capable of providing mass storage for the system 1200. In some implementations, the storage device 1230 is a non-transitory computer-readable medium. In various different implementations, the storage device 1230 may include, for example, a hard disk device, an optical disk device, a solid-date drive, a flash drive, or some other large capacity storage device. For example, the storage device may store long-term data (e.g., database data, file system data, etc.). The input/output device 1240 provides input/output operations for the system 1200. In some implementations, the input/output device 1240 may include one or more network interface devices, e.g., an Ethernet card, a serial communication device, e.g., an RS-232 port, and/or a wireless interface device, e.g., an 802.11 card, a 3G wireless modem, or a 4G wireless modem. In some implementations, the input/output device may include driver devices configured to receive input data and send output data to other input/output devices, e.g., keyboard, printer and display devices 1260. In some examples, mobile computing devices, mobile communication devices, and other devices may be used.

In some implementations, at least a portion of the approaches described above may be realized by instructions that upon execution cause one or more processing devices to carry out the processes and functions described above. Such instructions may include, for example, interpreted instructions such as script instructions, or executable code, or other instructions stored in a non-transitory computer readable medium. The storage device 1230 may be implemented in a distributed way over a network, for example as a server farm or a set of widely distributed servers, or may be implemented in a single computing device.

Although an example processing system has been described in FIG. 12, embodiments of the subject matter, functional operations and processes described in this specification can be implemented in other types of digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible nonvolatile program carrier for execution by, or to control the operation of, a data processing apparatus. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. The computer storage medium can be a machine-readable storage device, a machine-readable storage substrate, a random or serial access memory device, or a combination of one or more of them.

The term “system” may encompass all kinds of apparatus, devices, and machines for processing data, including by way of example a programmable processor, a computer, or multiple processors or computers. A processing system may include special purpose logic circuitry, e.g., an FPGA (field programmable gate array), an ASIC (application specific integrated circuit), or a programmable general purpose microprocessor or microcontroller. A processing system may include, in addition to hardware, code that creates an execution environment for the computer program in question, e.g., code that constitutes processor firmware, a protocol stack, a database management system, an operating system, or a combination of one or more of them.

A computer program (which may also be referred to or described as a program, software, a software application, a module, a software module, a script, or code) can be written in any form of programming language, including compiled or interpreted languages, or declarative or procedural languages, and it can be deployed in any form, including as a standalone program or as a module, component, subroutine, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA, an ASIC, or a programmable general purpose microprocessor or microcontroller.

Computers suitable for the execution of a computer program can include, by way of example, general or special purpose microprocessors or both, or any other kind of central processing unit. Generally, a central processing unit will receive instructions and data from a read-only memory or a random access memory or both. A computer generally includes a central processing unit for performing or executing instructions and one or more memory devices for storing instructions and data. Generally, a computer will also include, or be operatively coupled to receive data from or transfer data to, or both, one or more mass storage devices for storing data, e.g., magnetic disks, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's user device in response to requests received from the web browser.

Embodiments of the subject matter described in this specification can be implemented in a computing system that includes a back end component, e.g., a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship between client and server arises by virtue of computer programs running on the respective computers and having a client-server relationship with each other.

While this specification contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

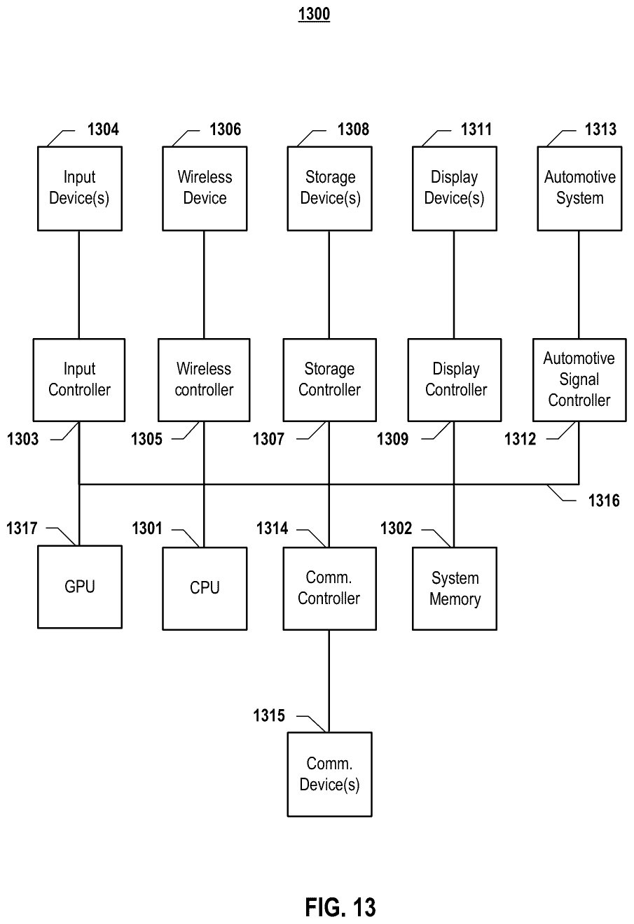

FIG. 13 depicts a simplified block diagram of a computing device/information handling system (or computing system) according to embodiments of the present disclosure. It will be understood that the functionalities shown for system 1300 may operate to support various embodiments of an information handling system—although it shall be understood that an information handling system may be differently configured and include different components.

As illustrated in FIG. 13, system 1300 includes one or more central processing units (CPU) 1301 that provide(s) computing resources and control(s) the computer. CPU 1301 may be implemented with a microprocessor or the like, and may also include one or more graphics processing units (GPU) 1317 and/or a floating point coprocessor for mathematical computations. System 1300 may also include a system memory 1302, which may be in the form of random-access memory (RAM), read-only memory (ROM), or both.

A number of controllers and peripheral devices may also be provided. For example, an input controller 1303 represents an interface to various input device(s) 1304, such as a keyboard, mouse, or stylus. There may also be a wireless controller 1305, which communicates with a wireless device 1306. System 1300 may also include a storage controller 1307 for interfacing with one or more storage devices 1308, each of which includes a storage medium such as a magnetic tape or disk, or an optical medium that might be used to record programs of instructions for operating systems, utilities, and applications, which may include embodiments of programs that implement various aspects of the techniques described herein. Storage device(s) 1308 may also be used to store processed data or data to be processed in accordance with some embodiments. System 1300 may also include a display controller 1309 for providing an interface to a display device 1311, which may be a cathode ray tube (CRT), a thin film transistor (TFT) display, or other type of display. The computing system 1300 may also include an automotive signal controller 1312 for communicating with an automotive system 1313. A communications controller 1314 may interface with one or more communication devices 1315, which enables system 1300 to connect to remote devices through any of a variety of networks including the Internet, a cloud resource (e.g., an Ethernet cloud, a Fiber Channel over Ethernet (FCoE)/Data Center Bridging (DCB) cloud, etc.), a local area network (LAN), a wide area network (WAN), a storage area network (SAN), or through any suitable electromagnetic carrier signals including infrared signals.

In the illustrated system, all major system components may connect to a bus 1316, which may represent more than one physical bus. However, various system components may or may not be in physical proximity to one another. For example, input data and/or output data may be remotely transmitted from one physical location to another. In addition, programs that implement various aspects of some embodiments may be accessed from a remote location (e.g., a server) over a network. Such data and/or programs may be conveyed through any of a variety of machine-readable medium including, but not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Some embodiments may be encoded upon one or more non-transitory, computer-readable media with instructions for one or more processors or processing units to cause steps to be performed. It shall be noted that the one or more non-transitory, computer-readable media shall include volatile and non-volatile memory. It shall also be noted that alternative implementations are possible, including a hardware implementation or a software/hardware implementation. Hardware-implemented functions may be realized using ASIC(s), programmable arrays, digital signal processing circuitry, or the like. Accordingly, the “means” terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that some embodiments may further relate to computer products with a non-transitory, tangible computer-readable medium that has computer code thereon for performing various computer-implemented operations. The medium and computer code may be those specially designed and constructed for the purposes of the techniques described herein, or they may be of the kind known or available to those having skill in the relevant arts. Examples of tangible, computer-readable media include, but are not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Examples of computer code include machine code, such as produced by a compiler, and files containing higher level code that is executed by a computer using an interpreter. Some embodiments may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art will recognize no computing system or programming language is critical to the practice of the techniques described herein. One skilled in the art will also recognize that a number of the elements described above may be physically and/or functionally separated into sub-modules or combined together.

In embodiments, aspects of the techniques described herein (e.g., timing the emission of optical signals, processing received return signals, generating point clouds, performing one or more (e.g., all) of the steps of the methods described herein, etc.) may be implemented using machine learning and/or artificial intelligence technologies.

“Machine learning” generally refers to the application of certain techniques (e.g., pattern recognition and/or statistical inference techniques) by computer systems to perform specific tasks. Machine learning techniques may be used to build models based on sample data (e.g., “training data”) and to validate the models using validation data (e.g., “testing data”). The sample and validation data may be organized as sets of records (e.g., “observations” or “data samples”), with each record indicating values of specified data fields (e.g., “independent variables,” “inputs,” “features,” or “predictors”) and corresponding values of other data fields (e.g., “dependent variables,” “outputs,” or “targets”). Machine learning techniques may be used to train models to infer the values of the outputs based on the values of the inputs. When presented with other data (e.g., “inference data”) similar to or related to the sample data, such models may accurately infer the unknown values of the targets of the inference data set.

A feature of a data sample may be a measurable property of an entity (e.g., person, thing, event, activity, etc.) represented by or associated with the data sample. A value of a feature may be a measurement of the corresponding property of an entity or an instance of information regarding an entity. Features can also have data types. For instance, a feature can have an image data type, a numerical data type, a text data type (e.g., a structured text data type or an unstructured (“free”) text data type), a categorical data type, or any other suitable data type. In general, a feature's data type is categorical if the set of values that can be assigned to the feature is finite.

As used herein, “model” may refer to any suitable model artifact generated by the process of using a machine learning algorithm to fit a model to a specific training data set. The terms “model,” “data analytics model,” “machine learning model” and “machine learned model” are used interchangeably herein.

As used herein, the “development” of a machine learning model may refer to construction of the machine learning model. Machine learning models may be constructed by computers using training data sets. Thus, “development” of a machine learning model may include the training of the machine learning model using a training data set. In some cases (generally referred to as “supervised learning”), a training data set used to train a machine learning model can include known outcomes (e.g., labels or target values) for individual data samples in the training data set. For example, when training a supervised computer vision model to detect images of cats, a target value for a data sample in the training data set may indicate whether or not the data sample includes an image of a cat. In other cases (generally referred to as “unsupervised learning”), a training data set does not include known outcomes for individual data samples in the training data set.

Following development, a machine learning model may be used to generate inferences with respect to “inference” data sets. For example, following development, a computer vision model may be configured to distinguish data samples including images of cats from data samples that do not include images of cats. As used herein, the “deployment” of a machine learning model may refer to the use of a developed machine learning model to generate inferences about data other than the training data.

“Artificial intelligence” (AI) generally encompasses any technology that demonstrates intelligence. Applications (e.g., machine-executed software) that demonstrate intelligence may be referred to herein as “artificial intelligence applications,” “AI applications,” or “intelligent agents.” An intelligent agent may demonstrate intelligence, for example, by perceiving its environment, learning, and/or solving problems (e.g., taking actions or making decisions that increase the likelihood of achieving a defined goal). In many cases, intelligent agents are developed by organizations and deployed on network-connected computer systems so users within the organization can access them. Intelligent agents are used to guide decision-making and/or to control systems in a wide variety of fields and industries, e.g., security; transportation; risk assessment and management; supply chain logistics; and energy management. Intelligent agents may include or use models.

Some non-limiting examples of AI application types may include inference applications, comparison applications, and optimizer applications. Inference applications may include any intelligent agents that generate inferences (e.g., predictions, forecasts, etc.) about the values of one or more output variables based on the values of one or more input variables. In some examples, an inference application may provide a recommendation based on a generated inference. For example, an inference application for a lending organization may infer the likelihood that a loan applicant will default on repayment of a loan for a requested amount, and may recommend whether to approve a loan for the requested amount based on that inference. Comparison applications may include any intelligent agents that compare two or more possible scenarios. Each scenario may correspond to a set of potential values of one or more input variables over a period of time. For each scenario, an intelligent agent may generate one or more inferences (e.g., with respect to the values of one or more output variables) and/or recommendations. For example, a comparison application for a lending organization may display the organization's predicted revenue over a period of time if the organization approves loan applications if and only if the predicted risk of default is less than 20% (scenario #1), less than 10% (scenario #2), or less than 5% (scenario #3). Optimizer applications may include any intelligent agents that infer the optimum values of one or more variables of interest based on the values of one or more input variables. For example, an optimizer application for a lending organization may indicate the maximum loan amount that the organization would approve for a particular customer.

As used herein, “data analytics” may refer to the process of analyzing data (e.g., using machine learning models, artificial intelligence, models, or techniques) to discover information, draw conclusions, and/or support decision-making. Species of data analytics can include descriptive analytics (e.g., processes for describing the information, trends, anomalies, etc. in a data set), diagnostic analytics (e.g., processes for inferring why specific trends, patterns, anomalies, etc. are present in a data set), predictive analytics (e.g., processes for predicting future events or outcomes), and prescriptive analytics (processes for determining or suggesting a course of action).

Data analytics tools are used to guide decision-making and/or to control systems in a wide variety of fields and industries, e.g., security; transportation; risk assessment and management; supply chain logistics; and energy management. The processes used to develop data analytics tools suitable for carrying out specific data analytics tasks generally include steps of data collection, data preparation, feature engineering, model generation, and/or model deployment.

As used herein, “spatial data” may refer to data relating to the location, shape, and/or geometry of one or more spatial objects. Data collected by lidar systems, devices, and chips described herein may be considered spatial data. A “spatial object” may be an entity or thing that occupies space and/or has a location in a physical or virtual environment. In some cases, a spatial object may be represented by an image (e.g., photograph, rendering, etc.) of the object. In some cases, a spatial object may be represented by one or more geometric elements (e.g., points, lines, curves, and/or polygons), which may have locations within an environment (e.g., coordinates within a coordinate space corresponding to the environment). In some cases, a spatial object may be represented as a cluster of points in a 3D point-cloud.

As used herein, “spatial attribute” may refer to an attribute of a spatial object that relates to the object's location, shape, or geometry. Spatial objects or observations may also have “non-spatial attributes.” For example, a residential lot is a spatial object that that can have spatial attributes (e.g., location, dimensions, etc.) and non-spatial attributes (e.g., market value, owner of record, tax assessment, etc.). As used herein, “spatial feature” may refer to a feature that is based on (e.g., represents or depends on) a spatial attribute of a spatial object or a spatial relationship between or among spatial objects. As a special case, “location feature” may refer to a spatial feature that is based on a location of a spatial object. As used herein, “spatial observation” may refer to an observation that includes a representation of a spatial object, values of one or more spatial attributes of a spatial object, and/or values of one or more spatial features.

Spatial data may be encoded in vector format, raster format, or any other suitable format. In vector format, each spatial object is represented by one or more geometric elements. In this context, each point has a location (e.g., coordinates), and points also may have one or more other attributes. Each line (or curve) comprises an ordered, connected set of points. Each polygon comprises a connected set of lines that form a closed shape. In raster format, spatial objects are represented by values (e.g., pixel values) assigned to cells (e.g., pixels) arranged in a regular pattern (e.g., a grid or matrix). In this context, each cell represents a spatial region, and the value assigned to the cell applies to the represented spatial region.

“Computer vision” generally refers to the use of computer systems to analyze and interpret image data. In some embodiments, computer vision may be used to analyze and interpret data collected by lidar systems (e.g., point-clouds). Computer vision tools generally use models that incorporate principles of geometry and/or physics. Such models may be trained to solve specific problems within the computer vision domain using machine learning techniques. For example, computer vision models may be trained to perform object recognition (recognizing instances of objects or object classes in images), identification (identifying an individual instance of an object in an image), detection (detecting specific types of objects or events in images), etc.

Computer vision tools (e.g., models, systems, etc.) may perform one or more of the following functions: image pre-processing, feature extraction, and detection/segmentation. Some examples of image pre-processing techniques include, without limitation, image re-sampling, noise reduction, contrast enhancement, and scaling (e.g., generating a scale space representation). Extracted features may be low-level (e.g., raw pixels, pixel intensities, pixel colors, gradients, patterns and textures (e.g., combinations of colors in close proximity), color histograms, motion vectors, edges, lines, corners, ridges, etc.), mid-level (e.g., shapes, surfaces, volumes, patterns, etc.), or high-level (e.g., objects, scenes, events, etc.). The detection/segmentation function may involve selection of a subset of the input image data (e.g., one or more images within a set of images, one or more regions within an image, etc.) for further processing.

### Some Embodiments

Some embodiments may include any of the following:

(A1) A lidar device comprising a first circuit comprising a transmitter configured to emit an optical signal, wherein a power level of the optical signal is based on an operating parameter; a power monitoring circuit coupled to the first circuit and configured to measure, during emission of the optical signal, an indication of the power level of the optical signal; and at least one processor configured to determine, based on a comparison of the measured indication of the power level to a nominal indication of the power level, whether to adjust the operating parameter.

(A2) The lidar device of A1, wherein the transmitter comprises a laser diode.

(A3) The lidar device of A1 or A2, wherein the operating parameter comprises a control voltage.

(A4) The lidar device of any of A1 to A3, wherein the transmitter is configured to emit the optical signal upon receiving an electrical signal, wherein a magnitude of the electrical signal is based on the operating parameter.

(A5) The lidar device of any of A1 to A4, wherein the indication of the power level of the optical signal is based on an amount of electrical energy dissipated through the transmitter.

(A6) The lidar device of A5, wherein the amount of electrical energy dissipated through the transmitter is based on a change in a voltage of a capacitive load coupled to the transmitter.

(A7) The lidar device of any of A1 to A6, wherein the at least one processor, in determining whether to adjust the operating parameter, is configured to determine a differential between the measured indication of the power level and the nominal indication of the power level; and if the differential is greater than a threshold, adjust the operating parameter.

(A8) The lidar device of any of A1 to A6, wherein the at least one processor, in determining whether to adjust the operating parameter, is configured to: determine a differential between the measured indication of the power level and the nominal indication of the power level; and if the differential is less than a threshold, maintain the operating parameter without an adjustment thereto.

(A9) A vehicle comprising: at least one lidar system, wherein each lidar system (i) comprises the lidar device of A1, (ii) is configured to provide navigation and/or mapping for the vehicle, and (iii) is disposed in an interior of the vehicle and/or on an exterior of the vehicle.

(A10) A power monitoring and control method for a lidar device, the method comprising: emitting, by a transmitter of the lidar device, an optical signal, wherein a power level of the optical signal is based on an operating parameter; measuring, by a power monitoring circuit during the emitting of the optical signal, an indication of the power level of the optical signal; and determining, based on a comparison of the measured indication of the power level to a nominal indication of the power level, whether to adjust the operating parameter.

(A11) The method of A10, wherein the transmitter comprises a laser diode.

(A12) The method of A10 or A11, wherein the operating parameter comprises a control voltage.

(A13) The method of any of A10-A12, wherein emitting the optical signal comprises: providing an electrical signal to the transmitter, wherein a magnitude of the electrical signal is based on the operating parameter.

(A14) The method of any of A10-A13, wherein the indication of the power level of the optical signal is based on an amount of electrical energy dissipated through the transmitter.

(A15) The method of A14, wherein the amount of electrical energy dissipated through the transmitter is based on a change in a voltage of a capacitive load coupled to the transmitter.

(A16) The method of any of A10-A15, wherein determining whether to adjust the operating parameter comprises: determining a differential between the measured indication of the power level and the nominal indication of the power level; and if the differential is greater than a threshold, adjusting the operating parameter.

(A17) The method of any of A10-A15, wherein determining whether to adjust the operating parameter comprises: determining a differential between the measured indication of the power level and the nominal indication of the power level; and if the differential is less than a threshold, maintaining the operating parameter without an adjustment thereto.

### Terminology

The phrasing and terminology used herein is for the purpose of description and should not be regarded as limiting.

Measurements, sizes, amounts, and the like may be presented herein in a range format. The description in range format is provided merely for convenience and brevity and should not be construed as an inflexible limitation on the scope of the invention. Accordingly, the description of a range should be considered to have specifically disclosed all the possible subranges as well as individual numerical values within that range. For example, description of a range such as 1-20 meters should be considered to have specifically disclosed subranges such as 1 meter, 2 meters, 1-2 meters, less than 2 meters, 10-11 meters, 10-12 meters, 10-13 meters, 10-14 meters, 11-12 meters, 11-13 meters, etc.

Furthermore, connections between components or systems within the figures are not intended to be limited to direct connections. Rather, data or signals between these components may be modified, re-formatted, or otherwise changed by intermediary components. Also, additional or fewer connections may be used. The terms “coupled,” “connected,” or “communicatively coupled” shall be understood to include direct connections, indirect connections through one or more intermediary devices, wireless connections, and so forth.

Reference in the specification to “one embodiment,” “preferred embodiment,” “an embodiment,” “some embodiments,” or “embodiments” means that a particular feature, structure, characteristic, or function described in connection with the embodiment is included in at least one embodiment of the invention and may be in more than one embodiment. Also, the appearance of the above-noted phrases in various places in the specification is not necessarily referring to the same embodiment or embodiments.

The use of certain terms in various places in the specification is for illustration purposes only and should not be construed as limiting. A service, function, or resource is not limited to a single service, function, or resource; usage of these terms may refer to a grouping of related services, functions, or resources, which may be distributed or aggregated.

Furthermore, one skilled in the art shall recognize that: (1) certain steps may optionally be performed; (2) steps may not be limited to the specific order set forth herein; (3) certain steps may be performed in different orders; and (4) certain steps may be performed simultaneously or concurrently.

The term “approximately”, the phrase “approximately equal to”, and other similar phrases, as used in the specification and the claims (e.g., “X has a value of approximately Y” or “X is approximately equal to Y”), should be understood to mean that one value (X) is within a predetermined range of another value (Y). The predetermined range may be plus or minus 20%, 10%, 5%, 3%, 1%, 0.1%, or less than 0.1%, unless otherwise indicated.

The indefinite articles “a” and “an,” as used in the specification and in the claims, unless clearly indicated to the contrary, should be understood to mean “at least one.” The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements).

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements).

The use of “including,” “comprising,” “having,” “containing,” “involving,” and variations thereof, is meant to encompass the items listed thereafter and additional items.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous. Other steps or stages may be provided, or steps or stages may be eliminated, from the described processes. Accordingly, other implementations are within the scope of the following claims.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A lidar device comprising:
a first circuit comprising a transmitter configured to emit an optical signal, wherein a power level of the optical signal is based on an operating parameter;
a power monitoring circuit coupled to the first circuit and configured to measure, during emission of the optical signal, an indication of the power level of the optical signal; and
at least one processor configured to determine, based on a comparison of the measured indication of the power level to a nominal indication of the power level, whether to adjust the operating parameter.

2. The lidar device of claim 1, wherein the transmitter comprises a laser diode.

3. The lidar device of claim 1, wherein the operating parameter comprises a control voltage.

4. The lidar device of claim 1, wherein the transmitter is configured to emit the optical signal upon receiving an electrical signal, wherein a magnitude of the electrical signal is based on the operating parameter.

5. The lidar device of claim 1, wherein the indication of the power level of the optical signal is based on an amount of electrical energy dissipated through the transmitter.

6. The lidar device of claim 5, wherein the amount of electrical energy dissipated through the transmitter is based on a change in a voltage of a capacitive load coupled to the transmitter.

7. The lidar device of claim 1, wherein the at least one processor, in determining whether to adjust the operating parameter, is configured to:
determine a differential between the measured indication of the power level and the nominal indication of the power level; and
if the differential is greater than a threshold, adjust the operating parameter.

8. The lidar device of claim 1, wherein the at least one processor, in determining whether to adjust the operating parameter, is configured to:
determine a differential between the measured indication of the power level and the nominal indication of the power level; and
if the differential is less than a threshold, maintain the operating parameter without an adjustment thereto.

9. A vehicle comprising:
at least one lidar system, wherein each lidar system (i) comprises the lidar device of claim 1, (ii) is configured to provide navigation and/or mapping for the vehicle, and (iii) is disposed in an interior of the vehicle and/or on an exterior of the vehicle.

10. A power monitoring and control method for a lidar device, the method comprising:
emitting, by a transmitter of the lidar device, an optical signal, wherein a power level of the optical signal is based on an operating parameter;
measuring, by a power monitoring circuit during the emitting of the optical signal, an indication of the power level of the optical signal; and
determining, based on a comparison of the measured indication of the power level to a nominal indication of the power level, whether to adjust the operating parameter.

11. The method of claim 10, wherein the transmitter comprises a laser diode.

12. The method of claim 10, wherein the operating parameter comprises a control voltage.

13. The method of claim 10, wherein emitting the optical signal comprises:
providing an electrical signal to the transmitter, wherein a magnitude of the electrical signal is based on the operating parameter.

14. The method of claim 10, wherein the indication of the power level of the optical signal is based on an amount of electrical energy dissipated through the transmitter.

15. The method of claim 14, wherein the amount of electrical energy dissipated through the transmitter is based on a change in a voltage of a capacitive load coupled to the transmitter.

16. The method of claim 10, wherein determining whether to adjust the operating parameter comprises:
determining a differential between the measured indication of the power level and the nominal indication of the power level; and
if the differential is greater than a threshold, adjusting the operating parameter.

17. The method of claim 10, wherein determining whether to adjust the operating parameter comprises:
determining a differential between the measured indication of the power level and the nominal indication of the power level; and
if the differential is less than a threshold, maintaining the operating parameter without an adjustment thereto.
